(19) United States
(12) Patent Application Publication
(10) Pub. No.: US 2025/0169234 A1
(43) Pub. Date: May 22, 2025

(54) Light-Emitting Element and Display Device Including the Same

(71) Applicant: LG Display Co., Ltd., Seoul (KR)

(72) Inventors: DongWon Yang, Paju-si (KR); Hyowon Kwon, Paju-si (KR); Yuseop Shin, Bucheon-si (KR)

(21) Appl. No.: 18/821,145

(22) Filed: Aug. 30, 2024

(30) Foreign Application Priority Data
Nov. 22, 2023 (KR) 10-2023-0163243

(51) Int. Cl. H01L 33/20; H01L 25/16; H01L 33/00

(52) U.S. Cl. CPC H10H 20/819; H01L 25/167; H10H 20/013

(57) ABSTRACT

A light-emitting element comprises a first semiconductor layer; a light-emitting layer on the first semiconductor layer; a second semiconductor layer on the light-emitting layer; a second electrode on the second semiconductor layer; and a first electrode on the first semiconductor layer, the first electrode spaced apart from the light-emitting layer and the second semiconductor layer, wherein the first semiconductor layer comprises one or more concave patterns between the first electrode and the second electrode.

### CROSS-REFERENCE TO RELATED APPLICATION

This application claims the priority from Republic of Korea Patent Application No. 10-2023-0163243, filed on Nov. 22, 2023, which is hereby incorporated by reference in its entirety.

### BACKGROUND

### Field

The present disclosure relates to a light-emitting element and a display device including the same, and more particularly, to a light-emitting diode (LED) and a display device using the same.

### Description of Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light-emitting display device. Further, the LED has a fast-lighting speed, excellent luminous efficiency, and a strong impact resistance so that a stability is excellent and an image having a high luminance can be displayed.

### SUMMARY

An object to be achieved by the present disclosure is to provide a light-emitting element with improved light extraction efficiency and a display device including the same.

Another object to be achieved by the present disclosure is to provide a light-emitting element, in which a brightness deviation depending on a viewing angle is reduced, and a display device including the same.

Objects of the present disclosure are not limited to the above-mentioned objects, and other objects, which are not mentioned above, can be clearly understood by those skilled in the art from the following descriptions.

According to one or more embodiments of the present disclosure, there is provided a light-emitting element. The light-emitting element comprises a first semiconductor layer; a light-emitting layer on the first semiconductor layer; a second semiconductor layer on the light-emitting layer; a second electrode on the second semiconductor layer; and a first electrode on the first semiconductor layer, the first electrode spaced apart from the light-emitting layer and the second semiconductor layer, wherein the first semiconductor layer comprises one or more concave patterns between the first electrode and the second electrode.

According to one or more embodiments of the present disclosure, there is provided a display device. The display device comprises a substrate comprising a plurality of subpixels; a plurality of light-emitting elements in the plurality of subpixels on the substrate; a plurality of transistors on the substrate; and a connection electrode connecting the plurality of transistors and the plurality of light-emitting elements, wherein each of the plurality of light-emitting elements comprises one or more concave patterns on a side surface of each of the plurality of light-emitting elements, and wherein the connection electrode overlaps a part of a concave pattern of the one or more concave patterns.

Other detailed matters of the embodiments are included in the detailed description and the drawings.

According to the present disclosure, the light extraction pattern is on the side surface of the light-emitting element, such that the light-emitting element may be stably bonded to the panel.

According to the present disclosure, the electrode is in the concave pattern, such that the light-emitting element may be easily connected to the panel.

According to the present disclosure, it is possible to minimize or at least reduce the occurrence of stains caused by a change in viewing angle.

The effects according to the present disclosure are not limited to the contents exemplified above, and more various effects are included in the present disclosure.

### BRIEF DESCRIPTION OF DRAWINGS

The above and other embodiments, features and other advantages of the present disclosure will be more clearly understood from the following detailed description taken in conjunction with the accompanying drawings, in which:

FIG. 1 is a schematic cross-sectional view of a light-emitting element according to one or more embodiments of the present disclosure;

FIGS. 2A to 2G are process diagrams for explaining a method of manufacturing the light-emitting element according to one or more embodiments of the present disclosure;

FIGS. 3A to 3D are cross-sectional views of light-emitting elements according one or more embodiments of the present disclosure;

FIGS. 4A to 4D are graphs for explaining effects of the light-emitting elements in FIGS. 3A to 3D according one or more embodiments of the present disclosure;

FIG. 5 is a schematic cross-sectional view of a light-emitting element according to one or more embodiments of the present disclosure;

FIG. 6 is a schematic configuration view of a display device according to one or more embodiments of the present disclosure;

FIG. 7 is a cross-sectional view of a pixel area of the display device according to one or more embodiments of the present disclosure;

FIGS. 8A and 8B are cross-sectional views for explaining a method of manufacturing the display device according to one or more embodiments of the present disclosure;

FIG. 9 is a cross-sectional view of a pixel area of a display device according to one or more embodiments of the present disclosure; and

FIGS. 10A to 10F are process diagrams for explaining a method of manufacturing the display device according to one or more embodiments of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to embodiments of the present disclosure will be described in detail with reference to accompanying drawings.

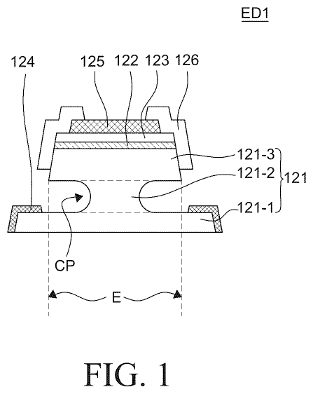

FIG. 1 is a schematic cross-sectional view of a light-emitting element according to one or more embodiments of the present disclosure.

With reference to FIG. 1, A light-emitting element ED1 includes a first semiconductor layer 121, a light-emitting layer 122, a second semiconductor layer 123, a first electrode 124, a second electrode 125, and an encapsulation layer 126.

The light-emitting element ED1 may have various structures such as lateral, vertical, and flip-chip structures. The lateral light-emitting element includes the first and second electrodes horizontally disposed at two opposite sides of a light-emitting layer. The vertical light-emitting element includes the first and seconds electrodes disposed at upper and lower sides of the light-emitting layer. The flip-chip light-emitting element is substantially identical in structure to the lateral light-emitting element. The lateral light-emitting element has the first and second electrodes horizontally disposed at the upper side of the light-emitting layer, whereas the flip-chip light-emitting element has the first and second electrodes horizontally disposed at the lower side of the light-emitting layer. Hereinafter, the description is made on the assumption that the light-emitting element ED1 has the lateral structure. However, the types of the light-emitting elements ED1 are not limited thereto.

The first semiconductor layer 121 is disposed at a lowermost side of the light-emitting element ED1. The first semiconductor layer 121 may be a layer formed by doping a particular material with n-type and p-type impurities. For example, the first semiconductor layer 121 may be a layer formed by doping a material, such as gallium nitride (GaN), indium aluminum phosphide (InAlP), or gallium arsenic (GaAs), with n-type and p-type impurities. In this case, the p-type impurity may be magnesium (Mg), zinc (Zn), beryllium (Be), or the like. The n-type impurity may be silicon (Si), germanium (Ge), tin (Sn), or the like. However, the present disclosure is not limited thereto. In the present disclosure, the first semiconductor layer 121 is defined as an n-type semiconductor layer, i.e., a layer doped with n-type impurities. However, the present disclosure is not limited thereto.

The first semiconductor layer 121 includes a first portion 121-1, a second portion 121-2, and a third portion 121-3.

The first portion 121-1 is a portion disposed at a lowermost side of the first semiconductor layer 121.

The second portion 121-2 is disposed on the first portion 121-1. The second portion 121-2 is a concave pattern CP.

The concave pattern CP is a portion formed concavely in a direction toward a center of the first semiconductor layer 121. Therefore, a minimum width of the second portion 121-2, in which the concave pattern CP is disposed, may be smaller than a width of a top surface of the first portion 121-1 and a width of a bottom surface of the third portion 121-3. In addition, a minimum width of the second portion 121-2 may be smaller than a width of a bottom surface of the first portion 121-1 and a width of a top surface of the third portion 121-3.

The concave pattern CP may be disposed to surround a lateral portion of the second portion 121-2. Meanwhile, FIG. 1 illustrates that the concave pattern CP has a round shape. However, the present disclosure is not limited thereto. The concave pattern CP may be formed to define an inclined surface. In this case, the concave pattern CP may be formed in a crystal direction of the first semiconductor layer 121. For example, in case that an angle of a crystal surface of a material constituting the first semiconductor layer 121 is 73°, the concave pattern CP may have an inclination angle of 73°. However, the present disclosure is not limited thereto. Meanwhile, FIG. 1 illustrates that one concave pattern CP is disposed on the second portion 121-2 in a cross-sectional view. However, the number of concave patterns CP is not limited thereto, and a plurality of concave patterns CP may be provided.

The third portion 121-3 is disposed on the second portion 121-2. A width of the bottom surface of the third portion 121-3 connected to the second portion 121-2 may be larger than a width of a top surface of the second portion 121-2. Therefore, the first semiconductor layer 121 may be disposed in an undercut shape. However, the present disclosure is not limited thereto. In addition, a width of the third portion 121-3 may increase in a downward direction. However, the present disclosure is not limited thereto.

The light-emitting layer 122 and the second semiconductor layer 123 are disposed on the first semiconductor layer 121.

A width of the light-emitting layer 122 and a width of the second semiconductor layer 123 may be smaller than the width of the top surface of the first semiconductor layer 121 disposed on the concave pattern CP. For example, the entire light-emitting layer 122 and the entire second semiconductor layer 123 may overlap the top surface of the first semiconductor layer 121, and the entire second semiconductor layer 123 may overlap the top surface of the light-emitting layer 122.

Meanwhile, a minimum width of the second portion 121-2, on which the concave pattern CP is disposed, may be smaller than a width of the light-emitting layer 122 and a width of the second semiconductor layer 123. However, the present disclosure is not limited thereto.

The light-emitting layer 122 may emit light by receiving positive holes and electrons from the first semiconductor layer 121 and the second semiconductor layer 123. The light-emitting layer 122 may be configured as a single layer or a multi-quantum well (MQW) structure. For example, the light-emitting layer 122 may be made of indium gallium nitride (InGaN), gallium nitride (GaN), or the like. However, the present disclosure is not limited thereto.

The second semiconductor layer 123 is disposed on the light-emitting layer 122. The second semiconductor layer 123 may be a layer formed by doping a particular material with n-type and p-type impurities. For example, the second semiconductor layer 123 may be a layer formed by doping a material, such as gallium nitride (GaN), indium aluminum phosphide (InAlP), or gallium arsenic (GaAs), with n-type and p-type impurities. Further, the p-type impurity may be magnesium (Mg), zinc (Zn), beryllium (Be), or the like. The n-type impurity may be silicon (Si), germanium (Ge), tin (Sn), or the like. However, the present disclosure is not limited thereto. In the present disclosure, the second semiconductor layer 123 is defined as a p-type semiconductor layer, i.e., a layer doped with p-type impurities. However, the present disclosure is not limited thereto.

The first electrode 124 is disposed on the first semiconductor layer 121. The first semiconductor layer 121 may be a semiconductor layer doped with n-type impurities, and the first electrode 124 may be a cathode. The first electrode 124 may be disposed on one of the side and top surfaces of the first semiconductor layer 121 exposed from the light-emitting layer 122 and the second semiconductor layer 123. For example, the first electrode 124 may be disposed on the top surface of the first portion 121-1 exposed by the second portion 121-2. The first electrode 124 may be disposed on the top surface of the first portion 121-1 extending from the concave pattern CP, and the top surface of the first portion 121-1 may be flat. In this case, the first electrode 124 may extend from the top surface of the first portion 121-1 and cover the side surface of the first portion 121-1. However, the present disclosure is not limited thereto.

Meanwhile, at least a part of the first electrode 124 may be disposed on the first portion 121-1 disposed outward of the light-emitting layer 122, the second semiconductor layer 123, and the second electrode 125. For example, at least a part of the top surface of the first portion 121-1 exposed by the second portion 121-2 may be disposed outward of the light-emitting layer 122, the second semiconductor layer 123, and the second electrode 125. In this case, the first electrode 124 may be disposed on the first portion 121-1 disposed outward of the light-emitting layer 122, the second semiconductor layer 123, and the second electrode 125.

For example, as illustrated in FIG. 1, a part of the first electrode 124 may be disposed outward of the two opposite ends E of the third portion 121-3. Therefore, in case that the light-emitting layer 122, the second semiconductor layer 123, and the second electrode 125 are disposed inward of the two opposite ends E of the third portion 121-3, the first electrode 124 may be disposed outward of the light-emitting layer 122, the second semiconductor layer 123, and the second electrode 125. Meanwhile, FIG. 1 illustrates that the first electrode 124 is disposed only outward of the two opposite ends E of the third portion 121-3. However, the present disclosure is not limited thereto. A part of the first electrode 124 may be disposed inward of the two opposite ends E of the third portion 121-3. Therefore, a part of the first electrode 124 may be disposed to overlap the light-emitting layer 122, the second semiconductor layer 123, and the second electrode 125. However, the present disclosure is not limited thereto.

The first electrode 124 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 125 is disposed on the second semiconductor layer 123. The second electrode 125 may be disposed on a top surface of the second semiconductor layer 123. In this case, the second semiconductor layer 123 may be a semiconductor layer doped with p-type impurities, and the second electrode 125 may be an anode. The second electrode 125 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The encapsulation layer 126 is disposed on the second semiconductor layer 123. The encapsulation layer 126 may protect the first semiconductor layer 121, the light-emitting layer 122, and the second semiconductor layer 123. The encapsulation layer may surround at least a part of the first semiconductor layer 121, at least a part of the light-emitting layer 122, at least a part of the second semiconductor layer 123, and at least a part of the second electrode 125. For example, the encapsulation layer 126 may be disposed only in an area disposed above the concave pattern CP. Therefore, the encapsulation layer 126 may be disposed to surround a partial area of the first semiconductor layer 121 disposed on the concave pattern CP and surround the light-emitting layer 122 and the second semiconductor layer 123. The encapsulation layer 126 may not adjoin the first electrode 124 and a partial area of the first semiconductor layer 121 disposed below the concave pattern CP. In addition, the second electrode 125 may be exposed from the encapsulation layer 126 to connect the light-emitting element ED1 to a display panel.

Meanwhile, the light-emitting elements ED1 may include light-emitting elements configured to emit light beams with different colors. For example, the light-emitting elements ED1 may include a red light-emitting element, a blue light-emitting element, and a green light-emitting element.

The red light-emitting element, the green light-emitting element, and the blue light-emitting element may include in common the first semiconductor layer 121, the light-emitting layer 122, the second semiconductor layer 123, the first electrode 124, the second electrode 125, and the encapsulation layer 126, but have the concave patterns CP different in shapes and numbers.

A spectrum emitted from the light-emitting element ED1 may be adjusted depending on an area, an angle, and a size of the concave pattern CP. Therefore, the shape and number of the concave pattern CP may be adjusted depending on the wavelength of the light emitted from the light-emitting element ED1, such that the light-emitting element ED1 may emit light with a wavelength within a particular range. Therefore, the shapes and numbers of the concave patterns CP may vary depending on the wavelengths of the light beams emitted from the red light-emitting element, the green light-emitting element, and the blue light-emitting element.

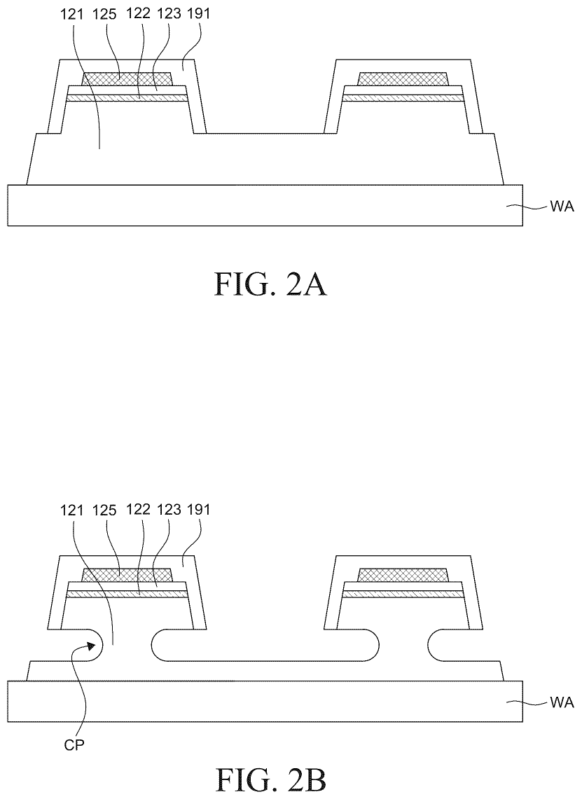

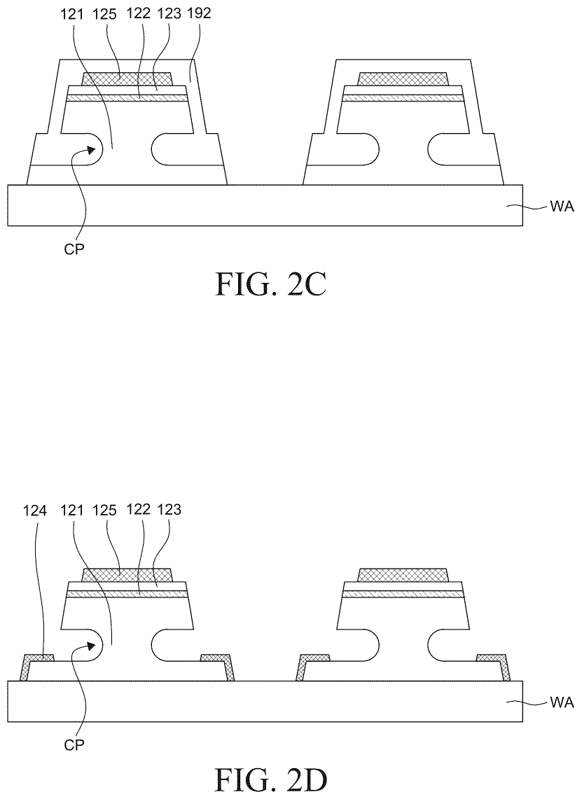

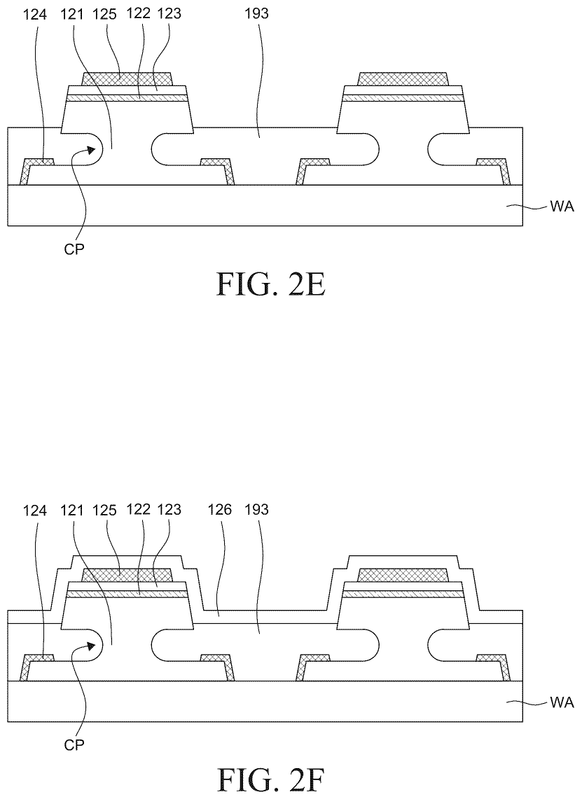

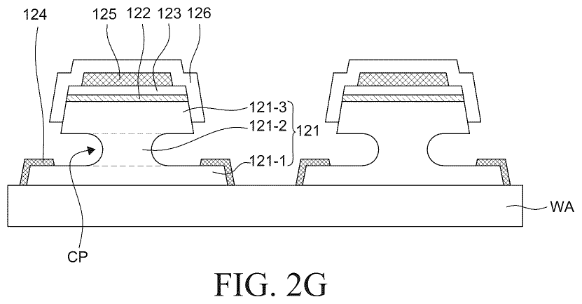

FIGS. 2A to 2G are process diagrams for explaining a method of manufacturing the light-emitting element according to one or more embodiments of the present disclosure.

With reference to FIG. 2A, the first semiconductor layer 121, the light-emitting layer 122, the second semiconductor layer 123, and the second electrode 125 are disposed on a wafer WA. The light-emitting layer 122 and the second semiconductor layer 123 may each be a state in which a partial area thereof is patterned by a mesa etching process. In this case, the mesa etching process may refer to a process of defining a light-emitting area of the light-emitting element ED1. The mesa etching process may refer to a process of etching the light-emitting layer 122 and the second semiconductor layer 123 disposed in an area corresponding to a non-light-emitting area of the light-emitting element ED1 while maintaining the light-emitting layer 122 and the second semiconductor layer 123 only in an area corresponding to the light-emitting area of the light-emitting element ED1 on the wafer WA. In this case, during the mesa etching process, a partial area of the first semiconductor layer 121 may also be etched. Therefore, a thickness of a portion of the first semiconductor layer 121 disposed outside the light-emitting layer 122 and the second semiconductor layer 123 may be smaller than a thickness of a portion of the first semiconductor layer 121 in an area that overlaps the light-emitting layer 122 and the second semiconductor layer 123.

Thereafter, a first cover layer 191 covers a mesa area. The first cover layer 191 may extend from the second electrode 125 and the top surface of the second semiconductor layer 123 and cover the second semiconductor layer 123, the side surface of the light-emitting layer 122, and a part of the side surface of the first semiconductor layer 121.

Next, with reference to FIG. 2B, an etching process is performed. The first cover layer 191 serves as a mask, and the first semiconductor layer 121 is etched in an area that is not covered by the first cover layer 191. In this case, the etching process is performed by wet etching. Therefore, with isotropic properties of the wet etching, the area exposed to the first cover layer 191 is etched in all directions without limitation to the direction. Therefore, the concave pattern CP is formed in the first semiconductor layer 121 disposed below the first cover layer 191, and the concave pattern CP may be formed to have an inclined surface or a round shape. Meanwhile, the size of the concave pattern CP may be adjusted depending on the etching process condition. That is, the concave pattern CP may be formed inward of the side surface of the second semiconductor layer 123 and the side surface of the light-emitting layer 122.

Next, an isolation process of separating the individual light-emitting elements ED1 from the wafer WA. With reference to FIG. 2C, a second cover layer 192 covers a part of the light-emitting layer 122, a part of the second semiconductor layer 123, a part of the second electrode 125, and a part of the first semiconductor layer 121. In this case, the second cover layer 192 covers the concave pattern CP exposed by the etching process. Therefore, the second cover layer 192 serves as a mask, and the first semiconductor layer 121 is etched in an area covered by the second cover layer 192.

Thereafter, with reference to FIG. 2D, the first electrode 124 is formed after the isolation process. After the second cover layer 192 is removed, the first electrode 124 is formed on the first semiconductor layer 121 and formed on the top surface of the first semiconductor layer 121 formed by the etching process. The first electrode 124 may be disposed on the first semiconductor layer 121 protruding outward of the second semiconductor layer 123 and the light-emitting layer 122. The first electrode 124 may extend from the top surface of the first semiconductor layer 121 and cover the side surface of the first semiconductor layer 121.

Next, with reference to FIG. 2E, a third cover layer 193 is formed on the light-emitting element ED1. The third cover layer 193 covers only a partial area of the first semiconductor layer 121. For example, the third cover layer 193 is formed below the second electrode 125, the second semiconductor layer 123, and the light-emitting layer 122. Therefore, the third cover layer 193 covers only the concave pattern CP, a lower area of the concave pattern CP, and the first electrode 124, and a part of an upper side of the first semiconductor layer 121, the second electrode 125, the second semiconductor layer 123, and the light-emitting layer 122 are exposed without being covered by the third cover layer 193.

Next, with reference to FIG. 2F, the encapsulation layer 126 is formed on the third cover layer 193. Therefore, a part of the upper side of the first semiconductor layer 121, the second electrode 125, the second semiconductor layer 123, and the light-emitting layer 122, which are exposed to the third cover layer 193, are covered by the encapsulation layer 126.

Next, with reference to FIG. 2G, the third cover layer 193 is removed. Therefore, a part of the upper side of the first semiconductor layer 121, the second electrode 125, the second semiconductor layer 123, and the light-emitting layer 122, which are not covered by the third cover layer 193, are maintained to be covered by the encapsulation layer 126. The concave pattern CP of the first semiconductor layer 121, the lower area of the concave pattern CP, and the first electrode 124, which have been covered by the third cover layer 193, are exposed by the encapsulation layer 126.

In the display device, a brightness deviation according to a viewing angle occurs in accordance with a shape of the light-emitting element and component tolerance. In case that a micro-light-emitting diode (micro-LED) is used for the light-emitting element, the side brightness may be higher than the front brightness. For example, the brightness may increase in a direction of 50 to 70 degrees, and the maximum brightness may be made in a direction of about 60 degrees. Therefore, a graph of the brightness distribution according to the viewing angle may have an ‘M’ shape, and a Mura phenomenon may occur.

Therefore, the concave pattern CP is disposed on the side surface of the light-emitting element ED1 according to one or more embodiments of the present disclosure. Therefore, the light beams, which enter the concave pattern CP at a threshold angle or smaller among the light beams generated by the light-emitting layer 122 of the light-emitting element ED1, may be extracted to the outside of the light-emitting element ED1. In this case, the propagation direction of the light extracted from the concave pattern CP may be changed by the surface of the concave pattern CP, and the light may propagate in a direction toward the front surface. Therefore, in the light-emitting element ED1 according to one or more embodiments of the present disclosure, the concave pattern CP may be disposed on the side surface of the light-emitting element ED1 to improve the light extraction efficiency, and a direction of an optical path may be changed from the direction toward the side surface to the direction toward the front surface to reduce a deviation of the viewing angle.

In addition, in the light-emitting element ED1 according to one or more embodiments of the present disclosure, the first electrode 124 is disposed on the first portion 121-1 exposed by the second portion 121-2. Therefore, the light-emitting element ED1 may be implemented to have the lateral structure, and a bonding metal forming process and a thermal compression process, which are performed to connect the vertical light-emitting element to the display panel, may be excluded. Therefore, in the light-emitting element ED1 according to one or more embodiments of the present disclosure, a process optimization may be implemented because the light-emitting element ED1 may be connected to the display panel without performing the bonding metal forming process and the thermal compression process.

In addition, the light-emitting element ED1 according to one or more embodiments of the present disclosure may include the concave pattern CP having the shape that varies depending on the wavelength of the light to be emitted. For example, the shape and number of the concave pattern CP may be adjusted depending on the wavelength of the light emitted from the light-emitting element ED1, such that the light-emitting element ED1 may emit light with a wavelength within a particular range.

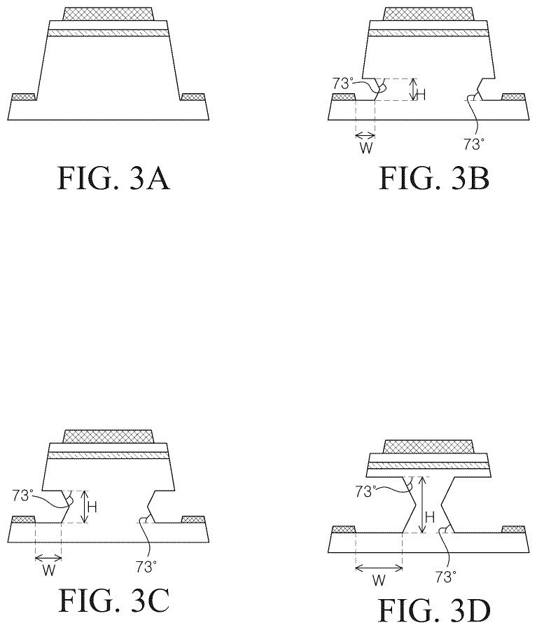

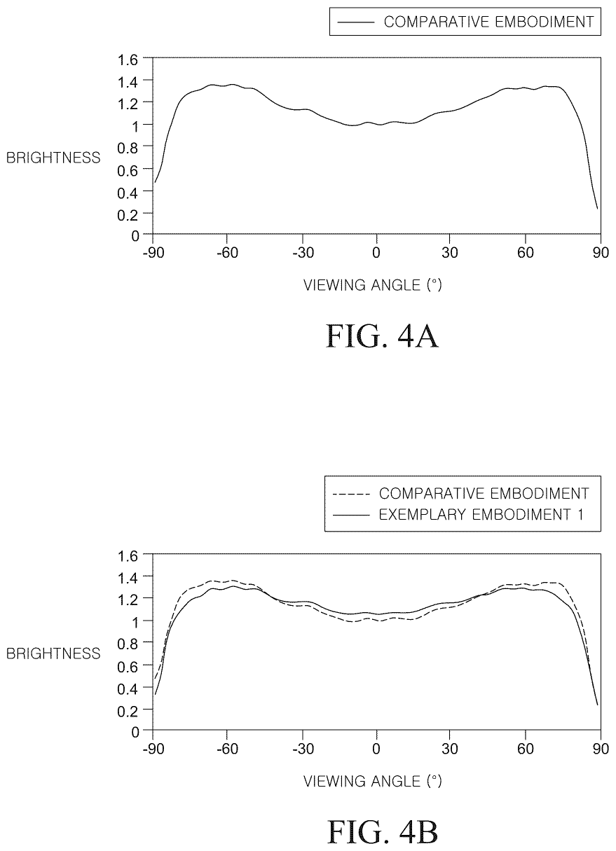

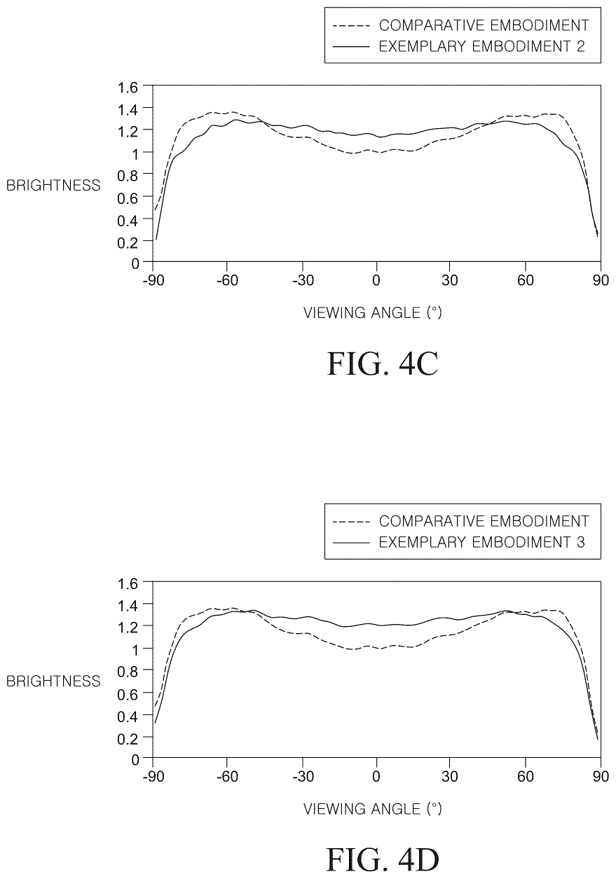

Hereinafter, the inclination angle of the concave pattern CP will be described with reference to FIGS. 3A to 4D.

FIGS. 3A to 3D are cross-sectional views of light-emitting elements according to one or more embodiments of the present disclosure. FIGS. 4A to 4D are graphs for explaining effects of the light-emitting elements in FIGS. 3A to 3D.

Various embodiments in FIGS. 3B to 3D relate to the light-emitting element ED1 in FIG. 1 according to one or more embodiments of the present disclosure. Embodiment 1 in FIG. 3B shows that a width W and a height H of the concave pattern CP are each 1 μm, Embodiment 2 in FIG. 3C shows that the width W and the height H of the concave pattern CP are each 2 μm, and Embodiment 3 in FIG. 3D shows that the width W and the height H of the concave pattern CP are each 3 μm. In this case, all the concave patterns CP in Embodiments 1 to 3 have an inclination of 73°. The comparative embodiment in FIG. 3A differs from embodiments in FIGS. 3B to 3D in that the concave pattern CP is not disposed.

FIG. 4A illustrates a brightness distribution in accordance with a viewing angle measured in the comparative embodiment in FIG. 3A, FIG. 4B illustrates a brightness distribution in accordance with a viewing angle measured in Embodiment 1 in FIG. 3B, FIG. 4C illustrates a brightness distribution in accordance with a viewing angle measured in Embodiment 2 in FIG. 3C, and FIG. 4D illustrates a brightness distribution in accordance with a viewing angle measured in Embodiment 3 in FIG. 3D. The X-axes in the graphs in FIGS. 4A to 4D indicate viewing angles. The Y-axes in the graphs in FIGS. 4A to 4D indicate brightness, and the brightness is set to 1 when the viewing angle in the direction toward the front surface is 0°.

With reference to FIGS. 4A to 4D, in the comparative embodiment and various embodiments, the brightness in the direction toward the side surface at 50° to 70° is higher than the brightness in the direction toward the front surface, and a maximum brightness is implemented at about 60°.

The results according to the graphs in FIGS. 4A to 4D are shown in Table 1 below.

TABLE 1

| | Viewing angle-brightness | Increase ratio of center |
|---|---|---|
| | ratio | brightness |
| Comparative | 36% | 100% |
| embodiment | | |
| Embodiment 1 | 21% | 113% |
| Embodiment 2 | 13% | 119% |
| Embodiment 3 | 9% | 121% |

The viewing angle-brightness ratio refers to a ratio of a maximum brightness measured in a direction toward the side surface, to the front brightness in the comparative embodiment and Embodiments 1 to 3.

The increase ratio of center brightness refers to a ratio of the front brightness measured in Embodiments 1 to 3 when the brightness at a viewing angle of 0° is 100% in the comparative embodiment.

With reference to FIG. 4A and Table 1, in the comparative embodiment, the viewing angle-brightness ratio is about 36%. Next, with reference to FIGS. 4B to 4D and Table 1, the viewing angle-brightness ratio in Embodiment 1 is about 21%, the viewing angle-brightness ratio in Embodiment 2 is about 13%, and the viewing angle-brightness ratio in Embodiment 3 is about 9%. Therefore, it can be ascertained that in comparison with the comparative embodiment in which the concave pattern CP is not disposed, the viewing angle-brightness ratio decreases, and the change in brightness depending on the viewing angle decreases in Embodiments 1 to 3 in which the concave pattern CP is disposed. Further, it can be ascertained that the viewing angle-brightness ratio decreases in the order of Embodiment 1, Embodiment 2, and Embodiment 3 in which the size of the concave pattern CP relatively increases.

In addition, with reference to FIGS. 4B to 4D and Table 1, the increase ratio of center brightness in Embodiment 1 is about 113%, the increase ratio of center brightness in Embodiment 2 is about 119%, and the increase ratio of center brightness in Embodiment 3 is about 121%. Therefore, it can be ascertained that the increase ratio of center brightness increases in the order of Embodiment 1, Embodiment 2, and Embodiment 3 in which the size of the concave pattern CP relatively increases.

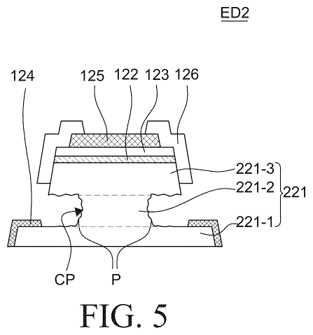

FIG. 5 is a schematic cross-sectional view of a light-emitting element according to one or more embodiments of the present disclosure. A light-emitting element ED2 in FIG. 5 is substantially identical in configuration to the light-emitting element ED1 in FIGS. 1 to 2G, except that a plurality of light extraction patterns P is disposed on the concave pattern CP of the light-emitting element ED2. Therefore, a repeated description will be omitted.

The light-emitting element ED2 may include the plurality of light extraction patterns P. The plurality of light extraction patterns P is disposed on the side surface of the light-emitting element ED2. For example, the plurality of light extraction patterns P is disposed along the concave pattern CP of a first semiconductor layer 221 and also disposed on a top surface of a first portion 221-1 and a bottom surface of a third portion 221-3 of the first semiconductor layer 221 exposed by the concave pattern CP. Meanwhile, in the light extraction pattern P, surface roughness of the light-emitting element ED2 may increase. For example, the surface roughness in the light extraction pattern P may be higher than the roughness of the side surface of the first portion 221-1 and the roughness of the side surface of the third portion 221-3. Meanwhile, the cross-sectional shape of the plurality of light extraction patterns P is not limited to the cross-sectional shape in FIG. 5.

In this case, the light extraction pattern P may be formed in a crystal direction. For example, in case that an angle of a crystal surface of a material constituting the first semiconductor layer 121 is 73°, the light extraction pattern P may have an inclination angle of 73°. However, the present disclosure is not limited thereto.

Meanwhile, the light-emitting elements ED2 may include light-emitting elements configured to emit light beams with different colors. For example, the light-emitting elements ED2 may include a red light-emitting element, a blue light-emitting element, and a green light-emitting element.

The red light-emitting element, the green light-emitting element, and the blue light-emitting element may include in common the first semiconductor layer 221, the light-emitting layer 122, the second semiconductor layer 123, the first electrode 124, the second electrode 125, and the encapsulation layer 126, but have the concave patterns CP different in shapes and numbers. Further, the shape of the light extraction pattern P may also vary.

A spectrum emitted from the light-emitting element ED2 may be adjusted depending on areas, angles, and sizes of the concave pattern CP and the light extraction pattern P. Therefore, the shape and number of the concave pattern CP may be adjusted depending on the wavelength of the light emitted from the light-emitting element ED2, such that the light-emitting element ED2 may emit light with a wavelength within a particular range. In addition, the angle and surface roughness of the light extraction pattern P may be adjusted depending on the wavelength of the light emitted from the light-emitting element ED2, such that the light-emitting element ED2 may emit light with a wavelength within a particular range. Therefore, the shapes and numbers of the concave patterns CP and the light extraction pattern P may vary depending on the wavelengths of the light beams emitted from the red light-emitting element, the green light-emitting element, and the blue light-emitting element.

The concave pattern CP is disposed on the side surface of the light-emitting element ED2 according to one or more embodiments of the present disclosure. Therefore, the light-emitting element ED2 according to one or more embodiments of the present disclosure may improve the light extraction efficiency, and a direction of an optical path may be changed from the direction toward the side surface to the direction toward the front surface to reduce a deviation of the viewing angle.

In addition, in the light-emitting element ED2 according to one or more embodiments of the present disclosure, a process optimization may be implemented because the light-emitting element ED2 may be connected to the display panel without performing the bonding metal forming process and the thermal compression process.

The plurality of light extraction patterns P is disposed on the concave pattern CP of the light-emitting element ED2 according to one or more embodiments of the present disclosure. Therefore, with the plurality of light extraction patterns P, the roughness of the light-emitting element ED2 may increase, the light extraction efficiency may be improved, and the front brightness may increase.

In addition, the plurality of light extraction patterns P is disposed on a side surface portion of the light-emitting element ED2 according to one or more embodiments, such that the light-emitting element ED2 may be stably fixed to a substrate 110. In case that the plurality of light extraction patterns is formed on the bottom surface of the light-emitting element to reduce the brightness deviation depending on the viewing angle, it may be difficult to stably fix the light-emitting element to the substrate because the flatness of the bottom surface of the light-emitting element is low. Therefore, in the light-emitting element ED2 according to one or more embodiments of the present disclosure, the plurality of light extraction patterns P is disposed on the side surface portion of the light-emitting element ED2, such that the light-emitting element ED2 may be stably fixed onto the substrate 110.

In addition, the light-emitting element ED2 according to one or more embodiments may include the concave pattern CP and the light extraction pattern P each having the shape that varies depending on the wavelength of the light to be emitted. For example, the shape and number of the concave pattern CP may be adjusted depending on the wavelength of the light emitted from the light-emitting element ED2, such that the light-emitting element ED2 may emit light with a wavelength within a particular range. In addition, the angle and surface roughness of the light extraction pattern P may be adjusted depending on the wavelength of the light emitted from the light-emitting element ED2, such that the light-emitting element ED2 may emit light with a wavelength within a particular range.

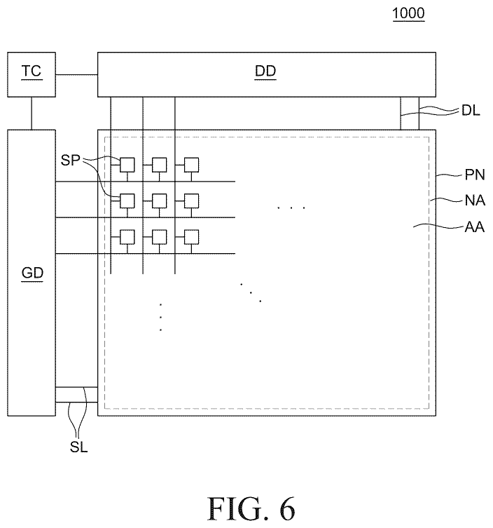

FIG. 6 is a schematic configuration view of a display device according to one or more embodiments of the present disclosure. For convenience of description, FIG. 6 illustrates only a display panel PN, a gate drive part GD, a data drive part DD, and a timing controller TC among various constituent elements of a display device 1000.

With reference to FIG. 6, the display device 1000 includes the display panel PN including a plurality of subpixels SP, the gate drive part GD configured to supply various types of signals to the display panel PN, and the timing controller TC configured to control the data drive part DD, the gate drive part GD, and the data drive part DD.

The gate drive part GD supplies a plurality of scan signals to a plurality of scan lines SL in response to a plurality of gate control signals provided from the timing controller TC. FIG. 6 illustrates that the single gate drive part GD is disposed to be spaced apart from one side of the display panel PN. However, the number and arrangement of the gate drive part GD are not limited thereto.

The data drive part DD converts image data, which are inputted from the timing controller TC, into a data voltage by using a reference gamma voltage in response to a plurality of data control signals provided from the timing controller TC. The data drive part DD may supply the converted data voltage to a plurality of data lines DL.

The timing controller TC aligns image data, which are inputted from the outside, and supplies the image data to the data drive part DD. The timing controller TC may generate the gate control signals and the data control signals by using synchronizing signals, i.e., dot clock signals, data enable signals, and horizontal/vertical synchronizing signals inputted from the outside. Further, the timing controller TC may control the gate drive part GD and the data drive part DD by supplying the generated gate control signals and data control signals to the gate drive part GD and the data drive part DD.

The display panel PN is configured to display images to a user and includes the plurality of subpixels SP.

The display panel PN may have a display area AA, and a non-display area NA configured to surround the display area AA.

The display area AA is an area of the display device 1000 in which images are displayed. The display area AA may include a plurality of subpixels SP constituting a plurality of pixels, and a circuit configured to operate the plurality of subpixels SP. The plurality of subpixels SP is minimum units that constitute the display area AA. The n subpixels SP may constitute a single pixel. A light-emitting element, a thin-film transistor for operating the light-emitting element, and the like may be disposed in each of the plurality of subpixels SP. The plurality of light-emitting elements may be differently defined depending on the type of the display panel PN. For example, in case that the display panel PN is an inorganic light-emitting display panel, the light-emitting element may be a light-emitting diode (LED) or a micro light-emitting diode (micro-LED).

A plurality of lines for transmitting various types of signals to the plurality of subpixels SP is disposed in the display area AA. For example, the plurality of lines may include the plurality of data lines DL for supplying data voltages to the plurality of subpixels SP, and the plurality of scan lines SL for supplying scan signals to the plurality of subpixels SP. The plurality of scan lines SL may extend in one direction in the display area AA and be connected to the plurality of subpixels SP. The plurality of data lines DL may extend in a direction different from one direction in the display area AA and be connected to the plurality of subpixels SP. In addition, a low-potential power line, a high-potential power line, and the like may be further disposed in the display area AA. However, the present disclosure is not limited thereto.

The non-display area NA may be defined as an area in which no image is displayed, i.e., an area extending from the display area AA. The non-display area NA may include link lines and pad electrodes for transmitting signals to the subpixels SP in the display area AA. Alternatively, the non-display area NA may include drive ICs such as gate drivers IC and data drivers IC.

However, the non-display area NA may be positioned on a rear surface of the display panel PN, i.e., a surface on which the subpixel SP is not present. Alternatively, the non-display area NA may be excluded. However, the present disclosure is not limited to the configuration illustrated in the drawings.

Meanwhile, the drive parts such as the gate drive part GD, the data drive part DD, and the timing controller TC may be connected to the display panel PN in various ways. For example, the gate drive part GD may be mounted in the non-display area NA by a gate-in-panel (GIP) method or mounted between the plurality of subpixels SP by a gate-in-active area (GIA) method in the display area AA. For example, the data drive part DD and the timing controller TC may be formed on a separate flexible film and the printed circuit board PCB. The data drive part DD and the timing controller TC may be electrically connected to the display panel PN by bonding the flexible film and the printed circuit board PCB to the pad electrode formed in the non-display area NA of the display panel PN.

In case that the gate drive part GD is mounted by the GIP method and the data drive part DD and the timing controller TC transmit signals to the display panel PN through the pad electrode in the non-display area NA, it is necessary to ensure an area of the non-display area NA at a predetermined level or higher in order to dispose the gate drive part GD and the pad electrode, which may increase a bezel.

Alternatively, in case that the gate drive part GD is mounted in the display area AA by the GIA method and a side line, which connects a signal line on a front surface of the display panel PN to the pad electrode on the rear surface of the display panel PN, is formed to bond the flexible film and the printed circuit board to the rear surface of the display panel PN, it is possible to minimize or at least reduce the non-display area NA on the front surface of the display panel PN. That is, in case that the gate drive part GD, the data drive part DD, and the timing controller TC are connected to the display panel PN by the above-mentioned method, a zero bezel in which the bezel is not substantially present may be implemented.

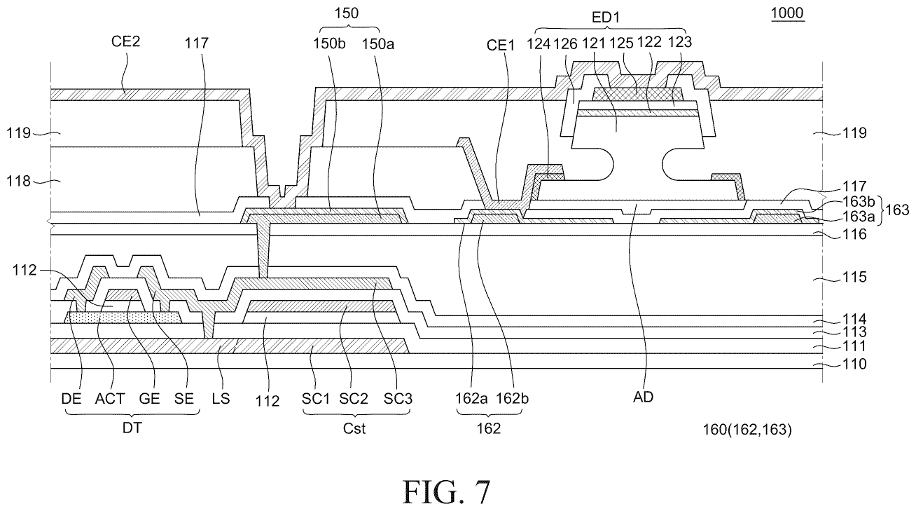

FIG. 7 is a cross-sectional view of a pixel area of the display device according to one or more embodiments of the present disclosure.

With reference to FIG. 7, the display device 1000 includes the substrate 110, a light-blocking layer LS, a buffer layer 111, a gate insulation layer 112, a first interlayer insulation layer 113, a first passivation layer 114, a first planarization layer 115, a second passivation layer 116, a third passivation layer 117, a second planarization layer 118, a third planarization layer 119, assembling electrodes 160, a connection electrode 150, the light-emitting element ED1, and a storage capacitor Cst.

With reference to FIG. 7, the display device 1000 includes the substrate 110. The substrate 110 may be a substrate, i.e., an insulation substrate configured to support the constituent elements disposed at an upper side of the display device 1000. The plurality of pixels SP may be formed on the substrate 110 so that images may be displayed. For example, the substrate 110 may be made of glass, resin, or the like. In addition, the substrate 110 may include polymer or plastic. In several embodiments, the substrate 110 may be made of a plastic material having flexibility.

The plurality of subpixels SP may be disposed in a plurality of rows and a plurality of columns on the substrate 110. The plurality of subpixels SP may each include the light-emitting element ED1 and a pixel circuit and independently emit light.

The plurality of subpixels SP may include a first subpixel, a second subpixel, and a third subpixel that emit light beams with different colors. For example, the first subpixel may be a red subpixel, the second subpixel may be a green subpixel, and the third subpixel may be a blue subpixel. However, the present disclosure is not limited thereto.

A first light-emitting element may be disposed on the first subpixel, a second light-emitting element may be disposed on the second subpixel, and a third light-emitting element may be disposed on the third subpixel. For example, the first light-emitting element may be a red light-emitting element, the second light-emitting element may be a green light-emitting element, and the third light-emitting element may be a blue light-emitting element. However, the present disclosure is not limited thereto.

A plurality of lines for transmitting various types of signals to the plurality of subpixels SP is disposed on the substrate 110. For example, the plurality of data lines DL, a plurality of high-potential power lines VDD, and a plurality of low-potential power lines, which extend in a column direction, may be disposed on the substrate 110. For example, a plurality of light-emitting control signal lines, a plurality of auxiliary high-potential power lines, a plurality of auxiliary low-potential power lines, and a plurality of scan lines, which extend in a row direction, may be disposed on the substrate 110. Further, the high-potential power line VDD, which extends in the column direction, and the auxiliary high-potential power line, which extends in the row direction, may be electrically connected to each other through a contact hole. In this case, the light-emitting control signal lines transmit light-emitting control signals to the pixel circuits of the plurality of subpixels SP to control light-emitting timings of the plurality of subpixels SP.

The pixel circuit for operating the light-emitting element ED1 is disposed in each of the plurality of subpixels SP on the substrate 110. The pixel circuit may include a plurality of thin-film transistors and a plurality of capacitors. For convenience of description, FIG. 7 illustrates only a driving transistor DT and the storage capacitor Cst among the components of the pixel circuit. However, the pixel circuit may further include a switching transistor, a sensing transistor, a light emission control transistor, and the like. However, the present disclosure is not limited thereto.

The light-blocking layer LS is provided on each of the plurality of subpixels SP and disposed on the substrate 110. The light-blocking layer LS may block light, which enters the transistor from a lower side of the substrate 110, and minimize or at least reduce a leakage current. For example, the light-blocking layer LS may block light entering an active layer ACT.

A first capacitor electrode SC1 is provided on each of the plurality of subpixels SP and disposed on the substrate 110. The first capacitor electrode SC1, together with other capacitor electrodes, may constitute the storage capacitor Cst. The first capacitor electrode SC1 may be integrated with the light-blocking layer LS.

The buffer layer 111 is disposed on the light-blocking layer LS and the first capacitor electrode SC1. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present disclosure is not limited thereto. However, the buffer layer 111 may be excluded in accordance with the type of substrate 110 or the type of transistor. However, the present disclosure is not limited thereto.

The driving transistor DT is disposed on the buffer layer 111 in each of the plurality of subpixels SP. The driving transistor DT is a transistor that supplies a drive current to the light-emitting element ED1. The driving transistor DT may be turned on and control the drive current flowing to the light-emitting element ED1.

The driving transistor DT includes the active layer ACT, a gate electrode GE, a source electrode SE, and a drain electrode DE.

The active layer ACT is disposed on the buffer layer 111. The active layer ACT may be made of a semiconductor material such as an oxide semiconductor, amorphous silicon, or polysilicon. However, the present disclosure is not limited thereto.

The gate insulation layer 112 is disposed on the active layer ACT. The gate insulation layer 112 is an insulation layer for insulating the active layer ACT and the gate electrode GE. The gate insulation layer 112 may be configured as a single layer or multilayer made of silicon oxide (SiOx) or silicon nitride (SiNx). However, the present disclosure is not limited thereto. Meanwhile, FIG. 7 illustrates that the gate insulation layer 112 is disposed only in an area that overlaps the gate electrode GE and a second capacitor electrode SC2. However, the present disclosure is not limited thereto.

The gate electrode GE is disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first interlayer insulation layer 113 is disposed on the gate electrode GE. Contact holes, through which the source electrode SE and the drain electrode DE are connected to the active layer ACT, are formed in the first interlayer insulation layer 113. The first interlayer insulation layer 113 is an insulation layer for protecting components disposed below the first interlayer insulation layer 113. The first interlayer insulation layer 113 may be configured as a single layer or multilayer made of silicon oxide (SiOx) or silicon nitride (SiNx). However, the present disclosure is not limited thereto.

The source electrode SE and the drain electrode DE are disposed on the first interlayer insulation layer 113 and electrically connected to the active layer ACT. The drain electrode DE may be electrically connected to the active layer ACT and the high-potential power line, and the source electrode SE may be electrically connected to the active layer ACT and the light-emitting element ED1. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The second capacitor electrode SC2 is disposed on the gate insulation layer 112. The second capacitor electrode SC2 may be one of the electrodes that constitute the storage capacitor Cst. The second capacitor electrode SC2 may be disposed to overlap the first capacitor electrode SC1. Although not illustrated in the drawings, the second capacitor electrode SC2 may be integrated with the gate electrode GE of the driving transistor DT and electrically connected to the gate electrode GE. However, the present disclosure is not limited thereto. The first capacitor electrode SC1 and the second capacitor electrode SC2 may be disposed to be spaced apart from each other with the buffer layer 111 and the gate insulation layer 112 interposed therebetween.

A third capacitor electrode SC3 is disposed on the first interlayer insulation layer 113. The third capacitor electrode SC3 may be an electrode that constitutes the storage capacitor Cst. The third capacitor electrode SC3 may be disposed to overlap the first capacitor electrode SC1 and the second capacitor electrode SC2. The third capacitor electrode SC3 may be integrated with the source electrode SE of the driving transistor DT and electrically connected to the source electrode SE. Further, the source electrode SE may also be electrically connected to the first capacitor electrode SC1 through contact holes formed in the first interlayer insulation layer 113 and the buffer layer 111. Therefore, the first capacitor electrode SC1 and the third capacitor electrode SC3 may be electrically connected to the source electrode SE of the driving transistor DT.

The storage capacitor Cst may store a potential difference between the gate electrode GE and the source electrode SE of the driving transistor DT while the light-emitting element ED1 emits light, such that a constant current may be supplied to the light-emitting element ED1. The storage capacitor Cst includes the first capacitor electrode SC1 formed on the substrate 110 and connected to the source electrode SE, the second capacitor electrode SC2 formed on the buffer layer 111 and the gate insulation layer 112, and the third capacitor electrode SC3 formed on the first interlayer insulation layer 113 and connected to a source electrode SE. The storage capacitor Cst may store a voltage between the gate electrode GE and the source electrode SE of the driving transistor DT.

The first passivation layer 114 is disposed on the driving transistor DT and the storage capacitor Cst. The first passivation layer 114 may be an insulation layer for protecting components disposed below the first passivation layer 114. The first passivation layer 114 may be configured as a single layer or multilayer made of silicon oxide (SiOx) or silicon nitride (SiNx). However, the present disclosure is not limited thereto.

The first planarization layer 115 is disposed on the first passivation layer 114. The first planarization layer 115 may planarize an upper portion of the substrate 110 on which the driving transistor DT and the storage capacitor Cst are disposed. The first planarization layer 115 may be configured as a single layer or multilayer and made of a photoresist or an acrylic-based organic material, for example. However, the present disclosure is not limited thereto.

The second passivation layer 116 is disposed on the first planarization layer 115. The second passivation layer 116 may be an insulation layer for protecting components disposed below the second passivation layer 116. The second passivation layer 116 may be configured as a single layer or multilayer made of silicon oxide (SiOx) or silicon nitride (SiNx). However, the present disclosure is not limited thereto.

The connection electrode 150 and the plurality of assembling electrodes 160 are disposed on the second passivation layer 116.

The connection electrode 150 is an electrode that electrically connects the driving transistor DT and a second connection electrode CE2. The connection electrode 150 may be electrically connected to the source electrode SE or the third capacitor electrode SC3 through contact holes formed in the second passivation layer 116, the first planarization layer 115, and the first passivation layer 114.

The connection electrode 150 may have a multilayer structure including a first connection layer 150a and a second connection layer 150b. The first connection layer 150a is disposed on the second passivation layer 116, and the second connection layer 150b is disposed to cover the first connection layer 150a. The second connection layer 150b may be disposed to surround both a top surface and a side surface of the first connection layer 150a.

The second connection layer 150b may be made of a material more resistant to corrosion than a material of the first connection layer 150a. Therefore, it is possible to minimize or at least reduce a short-circuit defect caused by migration between lines adjacent to the first connection layer 150a during the process of manufacturing the display device 1000. For example, the first connection layer 150a may be made of an electrically conductive material such as copper (Cu) and chromium (Cr). The second connection layer 150b may be made of molybdenum (Mo) and molybdenum titanium (MoTi). However, the present disclosure is not limited thereto.

The plurality of assembling electrodes 160 is disposed on the second passivation layer 116.

The assembling electrodes 160 include first assembling electrodes 162 and second assembling electrodes 163.

The plurality of first assembling electrodes 162 and the plurality of second assembling electrodes 163 may extend in the column direction in the plurality of subpixels SP and disposed to be spaced apart from one another at predetermined intervals.

The first assembling electrode 162 and the second assembling electrode 163 may be disposed to overlap the light-emitting element ED1. First, the first assembling electrode 162 may be disposed in an area corresponding to one side of the light-emitting element ED1. Among the assembling electrodes 160, the first assembling electrode 162 may be disposed in an area, which overlaps the low-potential power line, and electrically connected to the low-potential power line. The low-potential power line is a line for transmitting a low-potential power voltage to the light-emitting element ED1. The low-potential power line may extend in the column direction in each of the plurality of subpixels SP. For example, the low-potential power line may be disposed in each of the plurality of subpixels SP.

The second assembling electrode 163 may be spaced apart from the first assembling electrode 162 and disposed in an area corresponding to the other side of the light-emitting element ED1.

The plurality of assembling electrodes 160 each includes conductive layers 162a and 163a disposed on the second passivation layer 116, and clad layers 162b and 163b disposed on the conductive layers 162a and 163a and configured to cover all top and side surfaces of the conductive layers 162a and 163a.

The first assembling electrode 162 includes a first conductive layer 162a and a first clad layer 162b, and the second assembling electrode 163 includes a second conductive layer 163a and a second clad layer 163b.

The first conductive layer 162a and the second conductive layer 163a may not overlap the light-emitting element ED1. That is, an end of the first conductive layer 162a and an end of the second conductive layer 163a may be disposed outward of the light-emitting element ED1.

The first clad layer 162b of the first assembling electrode 162 may be disposed to cover the top and side surfaces of the first conductive layer 162a. In this case, the first clad layer 162b and the second clad layer 163b may extend from the end of the first conductive layer 162a and the end of the second conductive layer 163a toward a central portion of the light-emitting element ED1 and overlap the light-emitting element ED1.

The first conductive layer 162a and the second conductive layer 163a may be formed by the same process and made of the same material as the first connection layer 150a of the connection electrode 150. For example, the first conductive layer 162a and the second conductive layer 163a may be made of an electrically conductive material such as copper (Cu) and chromium (Cr). Further, the first clad layer 162b and the second clad layer 163b may be formed by the same process and made of the same material as the second connection layer 150b of the connection electrode 150. For example, the first clad layer 162b and the second clad layer 163b may each be made of a material more resistant to corrosion than materials of the first conductive layer 162a and the second conductive layer 163b. For example, the first clad layer 162b and the second clad layer 163b may each be made of molybdenum (Mo), molybdenum titanium (MoTi), and the like. However, the present disclosure is not limited thereto.

The third passivation layer 117 is disposed on the connection electrode 150 and the assembling electrode 160. The third passivation layer 117 may be an insulation layer for protecting components disposed below the third passivation layer 117. The third passivation layer 117 may be configured as a single layer or multilayer made of silicon oxide (SiOx) or silicon nitride (SiNx). However, the present disclosure is not limited thereto.

The plurality of light-emitting elements ED1 is disposed on the third passivation layer 117.

A partial area of the third passivation layer 117 may be opened in an area adjacent to the plurality of light-emitting elements ED1. For example, an area of the third passivation layer 117 adjacent to one side surface of two opposite surfaces of each of the plurality of light-emitting elements ED1, may be opened. For example, the third passivation layer 117 may expose a part of a top surface of the first assembling electrode 162 in the area adjacent to one side surface of each of the plurality of light-emitting elements ED1.

One or more light-emitting elements ED1 are disposed on the third passivation layer 117 in one subpixel SP. The light-emitting element ED1 is an element that emits light by receiving an electric current. The light-emitting elements ED1 may include the light-emitting elements ED1 configured to emit red light, green light, blue light, and the like. The light-emitting elements ED1 may implement light with various colors including white by using a combination of red light, green light, blue light, and the like. In addition, light beams with various colors may be implemented by using the light-emitting element ED1, which emits light with a particular color, and a photoconversion member that converts the light from the light-emitting element ED1 into light with a color different from the particular color.

The light-emitting element ED1 may emit light by receiving the drive current from the driving transistor DT. The size of the light-emitting element ED1 may vary depending on the type of the light-emitting element ED1. In this case, because the type of light-emitting element ED1 means the type of light to be emitted, the size of the light-emitting element ED1 may vary depending on whether the light-emitting element ED1 is the red light-emitting element, the green light-emitting element, or the blue light-emitting element. The light-emitting element may exhibit different types of luminous efficiency in accordance with the color of the light to be emitted. Therefore, the sizes of the light-emitting elements ED1 may be determined depending on the efficiency of the light-emitting element ED1 so that the light-emitting elements, which emit light beams with different colors, emit light beams with the same brightness.

For example, in case that the luminous efficiency of the light-emitting element, which emits light with a particular color, is relatively low, the light-emitting element may be formed to have a larger size than the other light-emitting elements to emit light with the same brightness as the other light-emitting elements. However, the present disclosure is not limited thereto.

With reference to FIG. 7, the light-emitting element ED1 includes the first semiconductor layer 121, the light-emitting layer 122, the second semiconductor layer 123, the first electrode 124, the second electrode 125, and the encapsulation layer 126. Hereinafter, the description is made on the assumption that the plurality of light-emitting elements ED1 has the lateral structure. However, the types of the plurality of light-emitting elements ED1 are not limited thereto. In addition, in FIG. 7, the plurality of light-emitting elements ED1 is described as adopting the light-emitting element ED1 described with reference to FIGS. 1 to 2G. However, the present disclosure is not limited thereto. All the light-emitting elements ED2 according to one or more embodiments of the present disclosure described with reference to FIG. 5 may be applied. Because the plurality of light-emitting elements ED1 has been described in detail with reference to FIGS. 1 to 2G, a repeated description will be omitted.

A bonding layer AD may be disposed between the plurality of light-emitting elements ED1, the third passivation layer 117, and the assembling electrode 160. The bonding layer AD may be an organic film that temporarily fixes the light-emitting element ED1 during the process of self-assembling the light-emitting element ED1. When the organic film is formed to cover the light-emitting element ED1 during the process of manufacturing the display device 1000, a space between the light-emitting element ED1, the third passivation layer 117, and the assembling electrode 160 is filled with a part of the organic film, such that the organic film may temporarily fix the light-emitting element ED1 onto the third passivation layer 117 and the assembling electrode 160. Thereafter, even though the organic film is removed, a part of the organic film, which permeates into a lower portion of the light-emitting element ED1, may remain without being removed, thereby defining the bonding layer. The bonding layer AD may be made of a photoresist or an organic material, for example, an acrylic-based organic material. However, the present disclosure is not limited thereto.

The second planarization layer 118 is disposed on the third passivation layer 117. The second planarization layer 118 may be configured as a single layer or multilayer and made of a photoresist or an acrylic-based organic material, for example. However, the present disclosure is not limited thereto.

In addition, the second planarization layer 118 may be disposed to surround a part of the side surface portion of each of the plurality of light-emitting elements ED1. For example, the second planarization layer 118 may be disposed to surround a lower side surface of the first semiconductor layer 121 extending from the bottom surface of the first semiconductor layer 121 of each of the plurality of light-emitting elements ED1 on the third passivation layer 117 and the assembling electrode 160. In this case, a bottom surface of the second planarization layer 118 may be disposed below a top surface of the first electrode 124 of each of the plurality of light-emitting elements ED1. However, the present disclosure is not limited thereto.

A first connection electrode CE1 is disposed on the second planarization layer 118. The first connection electrode CE1 may be disposed on the side surface of the light-emitting element ED1 and electrically connect the light-emitting element ED1 and the assembling electrode 160. The first connection electrode CE1 may be disposed in an area, which overlaps the first assembling electrode 162, and surround at least a part of the first semiconductor layer 121 and at least a part of the first electrode 124 of the light-emitting element ED1. The first connection electrode CE1 may be disposed to overlap a part of the concave pattern CP of the light-emitting element ED1 and connected to the first electrode 124 of the light-emitting element ED1.

In this case, the first connection electrode CE1 may be electrically connected to the first assembling electrode 162 exposed by the third passivation layer 117, in an area in which the third passivation layer 117 is opened. In addition, the first connection electrode CE1 may be disposed on the first electrode 124 of the first light-emitting element ED1 and extend to an upper side of the second planarization layer 118.

Meanwhile, the first electrode 124 of the first light-emitting element ED1 may be electrically connected to the first assembling electrode 162 without being connected to the second assembling electrode 163, such that the first electrode 124 of the first light-emitting element ED1 may be in a state of being insulated directly from the second assembling electrode 163. However, the present disclosure is not limited thereto. For example, FIG. 7 illustrates that the first connection electrode CE1 is not disposed on the other side surface of the light-emitting element ED1. However, the present disclosure is not limited thereto. The first connection electrode CE1 may be disposed to surround the side surface of the light-emitting element ED1. Therefore, the first connection electrode CE1 may be electrically connected to both the first assembling electrode 162 and the second assembling electrode 163. However, the present disclosure is not limited thereto.

The third planarization layer 119 is disposed on the light-emitting element ED1 and the first connection electrode CE1. The third planarization layer 119 may planarize the upper portion of the substrate 110 on which the light-emitting element ED1 is disposed. The third planarization layer 119, together with the bonding layer AD, may fix the light-emitting element ED1 onto the substrate 110.

Therefore, the third planarization layer 119 may be disposed on one side surface of the light-emitting element ED1 and adjoin the first connection electrode CE1, and the third planarization layer 119 may be disposed on the other side surface of the light-emitting element ED1 and adjoin the side surface of the light-emitting element. Meanwhile, the concave pattern CP of the light-emitting element ED1 may be filled with the third planarization layer 119. However, the present disclosure is not limited thereto.

Meanwhile, the drawings illustrate that the third planarization layer 119 is a single layer. However, the present disclosure is not limited thereto. The third planarization layer 119 may be configured as a single layer or multilayer and made of a photoresist or an acrylic-based organic material, for example. However, the present disclosure is not limited thereto. The second connection electrode CE2 is disposed on the third planarization layer 119.

The second connection electrode CE2 is an electrode that electrically connects the plurality of light-emitting elements ED1 and the connection electrode 150. With reference to FIG. 7, the second connection electrode CE2 may be electrically connected to the connection electrode 150 and the driving transistor DT through a contact hole formed in the second planarization layer 118.

The second connection electrode CE2 may be made of an electrically conductive material, e.g., a transparent conductive material such as indium tin oxide (ITO) or indium zinc oxide (IZO). However, the present disclosure is not limited thereto.

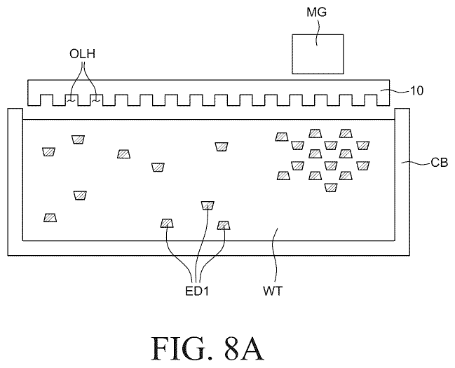

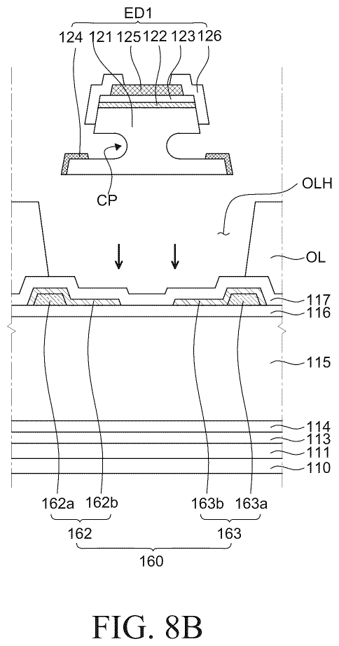

Hereinafter, a method of manufacturing the display device 1000 according to one or more embodiments of the present disclosure will be described with reference to FIGS. 8A and 8B.

FIGS. 8A and 8B are cross-sectional views for explaining a process of manufacturing the display device according to one or more embodiments of the present disclosure.

With reference to FIG. 8A, the light-emitting element ED1 is loaded into a chamber CB filled with a fluid WT. The fluid WT may include water or the like, and the chamber CB filled with the fluid WT may have a shape opened at an upper side thereof.

Next, a mother substrate 10 may be positioned on the chamber CB filled with the light-emitting elements ED1. The mother substrate 10 is a substrate including a plurality of substrates 110 constituting the display device 1000, and the mother substrate 10 may be cut and divided into the plurality of substrates 110 later. In order to self-assemble the plurality of light-emitting elements ED1, the mother substrate 10 having an organic layer OL additionally formed on the plurality of low-potential power lines and the third passivation layer 117 may be used.

Specifically, with reference to FIG. 8B, the buffer layer 111, the first interlayer insulation layer 113, the first passivation layer 114, the first planarization layer 115, and the second passivation layer 116 are sequentially formed on the substrate 110 together with the plurality of lines and the pixel circuit, and the assembling electrode 160 on the second passivation layer 116.

After the display device 1000 is completely manufactured, the assembling electrodes 160 may serve as a pair of low-potential power lines. During the process of manufacturing the display device 1000, different voltages may be applied to the two adjacent assembling electrodes 160. After the process of manufacturing the display device 1000 is completed, the same low-potential power voltage may be applied to the two adjacent assembling electrodes 160.

The assembling electrodes 160 include the first assembling electrode 162 and the second assembling electrode 163.

The first assembling electrode 162 is disposed on the second passivation layer 116. The first assembling electrode 162 includes the first clad layer 162b configured to cover the first conductive layer 162a and the first conductive layer 162a.

The second assembling electrode 163 is disposed on the second passivation layer 116. The second assembling electrode 163 includes the second clad layer 163b configured to cover the second conductive layer 163a and the second conductive layer 163a.

Next, the third passivation layer 117 is formed on the assembling electrode 160, and the organic layer OL having an opening portion OLH is formed on the third passivation layer 117. The opening portion OLH of the organic layer OL may correspond to the area in which the light-emitting element ED1 is self-assembled. The opening portion OLH of the organic layer OL may overlap the assembling electrode 160. The organic layer OL is removed after the light-emitting element ED1 is self-assembled, and the organic layer OL is not present in the display device 1000 when the manufacturing process is completed.

Therefore, the substrate 110 and the plurality of light-emitting elements ED1, which are formed to the organic layer OL illustrated in FIG. 8B, may be loaded into the chamber CB filled with the fluid WT, and an electric field may be formed by applying an alternating current voltage to the assembling electrode 160. Therefore, an electric field may be formed between the first assembling electrode 162 and the second assembling electrode 163.

The light-emitting element ED1 may have a polarity by being dielectrically polarized by the electric field. Further, the dielectrically polarized light-emitting element ED1 may be fixed or moved in a particular direction by dielectrophoresis (DEP), i.e., the electric field. Therefore, the dielectrophoresis may be used to self-assemble the plurality of light-emitting elements ED1 onto the assembling electrode 160.

Lastly, when the light-emitting element ED1 is completely self-assembled, the organic layer OL is removed, and the other components, such as the bonding layer AD, the first connection electrode CE1, the second connection electrode CE2, the second planarization layer 118, and the third planarization layer 119, are formed, such that the process of manufacturing the display device 1000 may be completed.

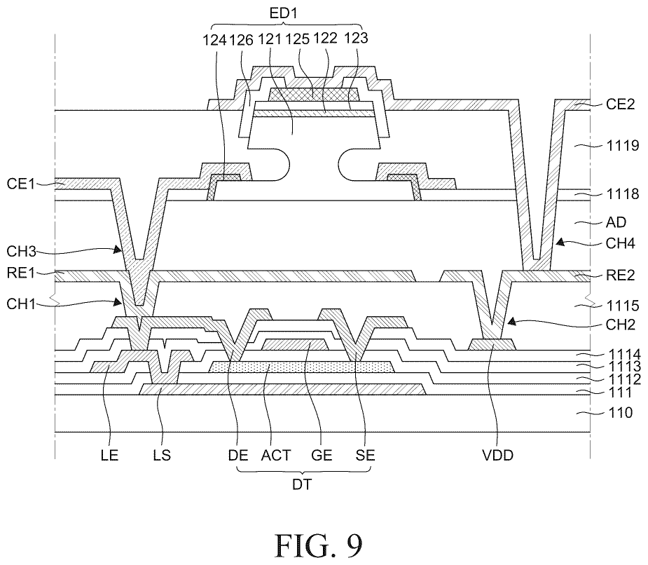

FIG. 9 is a cross-sectional view of a pixel area of a display device according to one or more embodiments of the present disclosure.

With reference to FIG. 9, the substrate 110, the buffer layer 111, a gate insulation layer 1112, a first interlayer insulation layer 1113, a second interlayer insulation layer 1114, a first planarization layer 1115, the bonding layer AD, a second planarization layer 1118, a third planarization layer 1119, the driving transistor DT, the light-emitting element ED1, a plurality of reflective electrodes RE, a plurality of connection electrodes CE, the light-blocking layer LS, and an auxiliary electrode LE are disposed in each of a plurality of subpixels SP of a display device 1100 according to one or more embodiments of the present disclosure.

The light-blocking layer LS and the buffer layer 111 are disposed on the substrate 110 in each of the plurality of subpixels SP, and the driving transistor DT is disposed on the buffer layer 111. The driving transistor DT includes the active layer ACT, the gate electrode GE, the source electrode SE, and the drain electrode DE.

The active layer ACT is disposed on the buffer layer 111. The active layer ACT may be made of a semiconductor material such as an oxide semiconductor, amorphous silicon, or polysilicon. However, the present disclosure is not limited thereto.

The gate insulation layer 1112 is disposed on the active layer ACT. FIG. 9 illustrates that the gate insulation layer 1112 is disposed on the front surface of the substrate 110. However, the present disclosure is not limited thereto. The gate insulation layer 1112 may be disposed to overlap only the gate electrode GE.

The gate electrode GE is disposed on the gate insulation layer 1112.

The first interlayer insulation layer 1113 and the second interlayer insulation layer 1114 are disposed on the gate electrode GE. Contact holes, through which the source electrode SE and the drain electrode DE are connected to the active layer ACT, are formed in the first interlayer insulation layer 1113 and the second interlayer insulation layer 1114.

The source electrode SE and the drain electrode DE are disposed on the second interlayer insulation layer 1114 and electrically connected to the active layer ACT.

Meanwhile, in the present disclosure, the configuration has been described in which the first interlayer insulation layer 1113 and the second interlayer insulation layer 1114, i.e., the plurality of insulation layers is disposed between the gate electrode GE, the source electrode SE, and the drain electrode DE. However, only a single insulation layer may be disposed between the gate electrode GE, the source electrode SE, and the drain electrode DE. However, the present disclosure is not limited thereto.

Further, as illustrated in FIG. 9, in case that the plurality of insulation layers, such as the first interlayer insulation layer 1113 and the second interlayer insulation layer 1114, is disposed between the gate electrode GE, the source electrode SE, and the drain electrode DE, an electrode may be additionally formed between the first interlayer insulation layer 1113 and the second interlayer insulation layer 1114. The additionally formed electrode may define a capacitor together with other components disposed on the lower portion of the first interlayer insulation layer 1113 or the upper portion of the second interlayer insulation layer 1114.

The auxiliary electrode LE is disposed on the gate insulation layer 1112. The auxiliary electrode LE is an electrode that electrically connects the light-blocking layer LS disposed below the buffer layer 111, to any one of the source electrode SE and the drain electrode DE on the second interlayer insulation layer 114. For example, the light-blocking layer LS may be electrically connected to any one of the source electrode SE or the drain electrode DE through the auxiliary electrode LE so as not to be operated as a floating gate, thereby minimizing or at least reducing a change in threshold voltage of the driving transistor DT caused by the floating light-blocking layer LS. FIG. 9 illustrates that the light-blocking layer LS is connected to the drain electrode DE. However, the light-blocking layer LS may be connected to the source electrode SE. However, the present disclosure is not limited thereto.

The power line VDD is disposed on the second interlayer insulation layer 1114. The power line VDD may be electrically connected to the light-emitting element ED1 together with the driving transistor DT and allow the light-emitting element ED1 to emit light. The power line VDD may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first planarization layer 1115 is disposed on the driving transistor DT and the power line VDD. The first planarization layer 1115 may planarize the upper portion of the substrate 110 on which the driving transistor DT is disposed.

The plurality of reflective electrodes RE spaced apart from one another, is disposed on the first planarization layer 1115. The plurality of reflective electrodes RE may serve to electrically connect the light-emitting element ED1 to the power line VDD and the driving transistor DT and serve as a reflective plate that reflects light emitted from the light-emitting element ED1, to an upper portion of the light-emitting element ED1. The plurality of reflective electrodes RE may each be made of an electrically conductive material having excellent reflection performance and reflect the light emitted from the light-emitting element ED1, toward the upper portion of the light-emitting element ED1. For example, the plurality of reflective electrodes RE may be made by using an opaque conductive layer made of silver (Ag), aluminum (Al), molybdenum (Mo), titanium (Ti), or an alloy thereof, together with a transparent conductive layer made of indium tin oxide (ITO). However, the structure of the reflective plate RF is not limited thereto.

The plurality of reflective electrodes RE includes a first reflective electrode RE1 and a second reflective electrode RE2. The first reflective electrode RE1 may electrically connect the driving transistor DT and the light-emitting element ED1. The first reflective electrode RE1 may be connected to the source electrode SE or the drain electrode DE of the driving transistor DT through a contact hole CH1 formed in the first planarization layer 1115. Further, the first reflective electrode RE1 may be electrically connected to a first electrode 124 and a first semiconductor layer 121 of the light-emitting element ED1 through the first connection electrode CE1 to be described below.

The second reflective electrode RE2 may electrically connect the power line VDD and the light-emitting element ED1. The second reflective electrode RE2 may be connected to the power line VDD through a contact hole CH2 formed in the first planarization layer 1115, and electrically connected to a second electrode 125 and a second semiconductor layer 123 of the light-emitting element ED1 through the second connection electrode CE2 to be described below.

The bonding layer AD is disposed on the plurality of reflective electrodes RE. A third contact hole CH3, through which the first connection electrode CE1 is connected to the first reflective electrode RE1, is disposed in the bonding layer AD, and a fourth contact hole CH4, through which the second connection electrode CE2 is connected to the second reflective electrode RE2, is disposed in the bonding layer AD. The front surface of the substrate 110 may be coated with the bonding layer AD, and the bonding layer AD may fix the light-emitting element ED1 disposed on the bonding layer AD.

The plurality of light-emitting elements ED1 is disposed on the bonding layer AD in each of the plurality of subpixels SP.

With reference to FIG. 9, the light-emitting element ED1 includes the first semiconductor layer 121, the light-emitting layer 122, the second semiconductor layer 123, the first electrode 124, the second electrode 125, and the encapsulation layer 126. Hereinafter, the description is made on the assumption that the plurality of light-emitting elements ED1 has the lateral structure. However, the types of the plurality of light-emitting elements ED1 are not limited thereto. In addition, in FIG. 9, the plurality of light-emitting elements ED1 is described as adopting the light-emitting element ED1 described with reference to FIGS. 1 to 2G. However, the present disclosure is not limited thereto. All the light-emitting elements ED2 according to one or more embodiments of the present disclosure described with reference to FIG. 5 may be applied. Because the light-emitting element ED1 has been described in detail with reference to FIGS. 1 to 2G, a repeated description will be omitted.

Meanwhile, the light-emitting elements ED1 disposed in different subpixels SP may have different shapes. For example, in case that the first light-emitting element is disposed in the first subpixel, the second light-emitting element is disposed in the second subpixel, and the third light-emitting element is disposed in the third subpixel, the first light-emitting element, the second light-emitting element, and the third light-emitting element may have different shapes.

For example, a planar shape of the first semiconductor layer 121 of the first light-emitting element may be a circular shape. A planar shape of the first semiconductor layer 121 of the second light-emitting element may be an elliptical shape. A planar shape of the first semiconductor layer 121 of the third light-emitting element may be an elliptical shape. In this case, a ratio between a major axis and a minor axis of the third light-emitting element may be different from a ratio of the major axis and the minor axis of the second light-emitting element. The major axis of the third light-emitting element may be longer than the major axis of the second light-emitting element, and the minor axis of the third light-emitting element may be shorter than the minor axis of the second light-emitting element. However, the present disclosure is not limited thereto.

In the display device 1100 according to one or more embodiments of the present disclosure, the first light-emitting element is configured as a circular light-emitting element, the second light-emitting element is configured as a first elliptical light-emitting element, and the third light-emitting element is configured as a second elliptical light-emitting element different in planar shape from the second light-emitting element, such that the plurality of light-emitting elements ED1 may be distinguished. For example, during a process of self-assembling the light-emitting elements ED1, the plurality of light-emitting elements ED1 may be formed in different shapes, such that the plurality of light-emitting elements ED1 may be self-assembled at positions respectively corresponding to the plurality of subpixels SP. However, the shapes of the plurality of light-emitting elements ED1 are exemplary, and the present disclosure is not limited thereto.

The second planarization layer 1118 and the third planarization layer 1119 are disposed on the bonding layer AD. The second planarization layer 1118 may partially overlap the side surfaces of the plurality of light-emitting elements ED1 and fix and protect the plurality of light-emitting elements ED1.

Further, the first connection electrode CE1 is disposed on the second planarization layer 1118. The first connection electrode CE1 may be connected to the first reflective electrode RE1 through the third contact hole CH3 formed in the second planarization layer 1118 and the bonding layer AD. Therefore, the first connection electrode CE1 may be electrically connected to any one of the source electrode SE and the drain electrode DE of the driving transistor DT through the first reflective electrode RE1. Further, the first connection electrode CE1 may be connected to the first electrode 124 of each of the plurality of light-emitting elements ED1.

The first connection electrode CE1 may be disposed to surround the side surface of each of the plurality of light-emitting elements ED1.

The third planarization layer 1119 is disposed on the first connection electrode CE1 and the plurality of light-emitting elements ED1. The concave pattern CP of the light-emitting element ED1 may be filled with the third planarization layer 1119. However, the present disclosure is not limited thereto.

The second connection electrode CE2 is disposed on the third planarization layer 1119. The second connection electrode CE2 is an electrode that electrically connects the light-emitting element ED1 and the power line VDD. The second connection electrode CE2 may be connected to the second reflective electrode RE2 through the fourth contact hole CH4 formed in the third planarization layer 1119, the second planarization layer 1118, and the bonding layer AD. Therefore, the second connection electrode CE2 may be electrically connected to the power line VDD through the second reflective electrode RE2. Further, the second connection electrode CE2 may be connected to the second electrode 125 of each of the plurality of light-emitting elements ED1. Therefore, the second connection electrode CE2 may electrically connect the power line VDD and the second electrode 125 and the second semiconductor layer 123 of each of the plurality of light-emitting elements ED1.

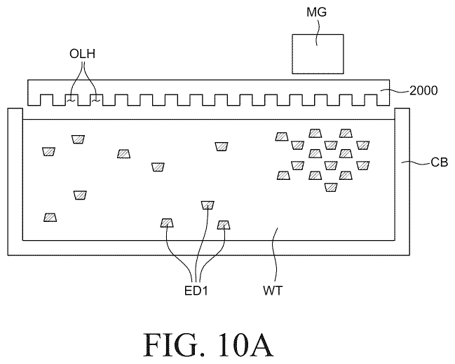

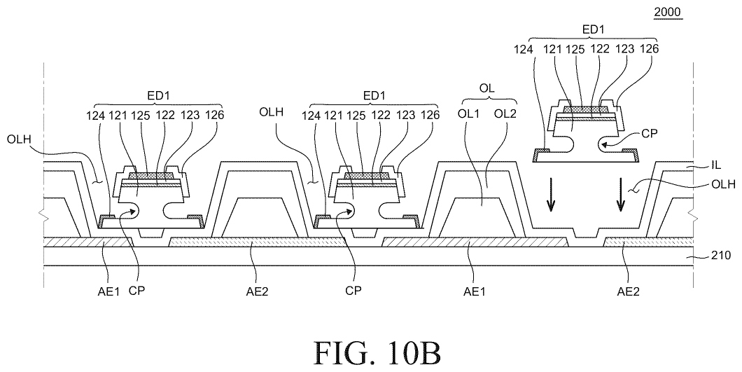

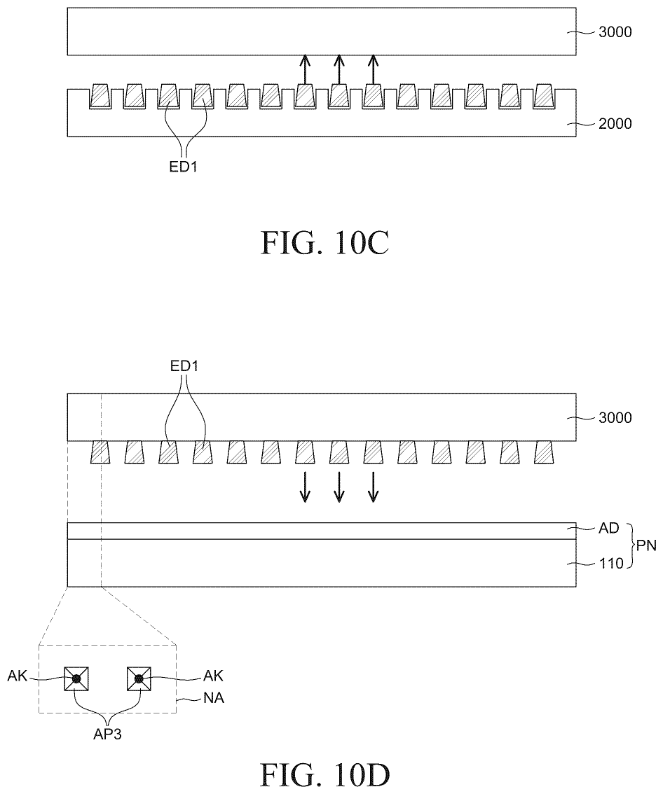

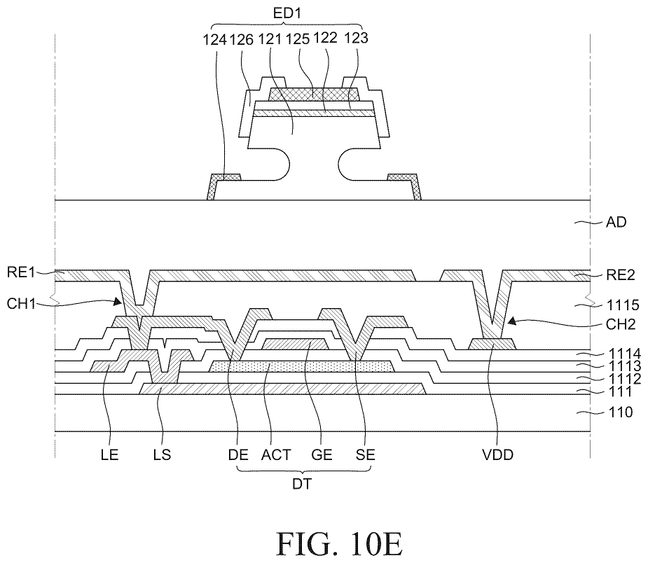

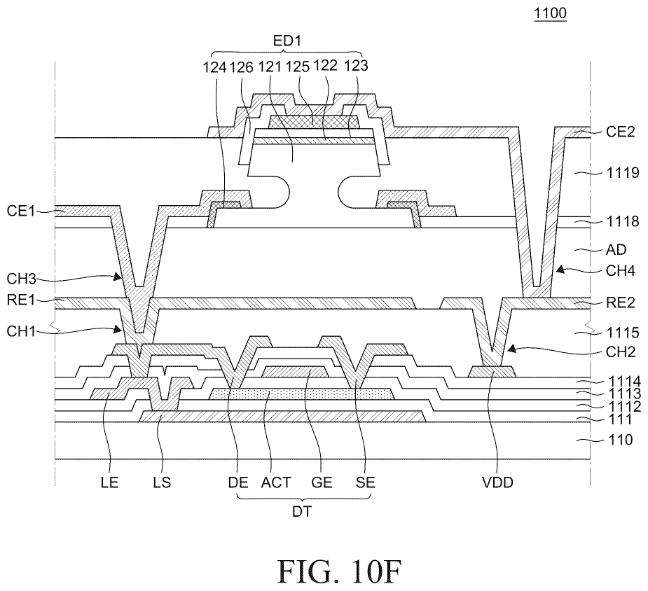

Hereinafter, a method of manufacturing the display device 1100 according to one or more embodiments of the present disclosure will be described with reference to FIGS. 10A to 10F.

FIGS. 10A to 10F are process diagrams for explaining a method of manufacturing the display device according to one or more embodiments of the present disclosure. FIGS. 10A and 10B are views for explaining a process of self-assembling the light-emitting element ED1 onto an assembling substrate 2000 according to one or more embodiments of the present disclosure. FIG. 10C is a view for explaining a process of transferring the light-emitting element ED1 on the assembling substrate 2000 to a donor 3000 according to one or more embodiments of the present disclosure. FIGS. 10D and 10E are views for explaining a process of transferring the light-emitting element ED1 on the donor 3000 to the display panel PN according to one or more embodiments of the present disclosure. FIG. 10F is a cross-sectional view of the display device 1100 for explaining a process of forming the first connection electrode CE1 and the second connection electrode CE2 according to one or more embodiments of the present disclosure.

With reference to FIG. 10A, the plurality of light-emitting elements ED1 is self-assembled onto the assembling substrate 2000.

First, the plurality of light-emitting elements ED1 grown on a wafer is loaded into the chamber CB filled with the fluid WT. The fluid WT may include water or the like, and the chamber CB filled with the fluid WT may have a shape opened at an upper side thereof.

Next, the assembling substrate 2000 may be positioned on the chamber CB filled with the light-emitting elements ED1. The assembling substrate 2000 may be disposed such that the organic layer OL having the plurality of opening portions OLH of the assembling substrate 2000 faces the chamber CB.

Next, a magnet MG may be positioned on the assembling substrate 2000. The light-emitting elements ED1, which are submerged or suspended on a bottom of the chamber CB, may be moved toward the assembling substrate 2000 by a magnetic force of the magnet MG.

In this case, the light-emitting element ED1 may include a magnetic element so that the light-emitting element ED1 may be moved by a magnetic field. For example, any one of the first electrode 124 and the second electrode 125 of the light-emitting element ED1 may include ferromagnetic materials such as iron (Fe), cobalt (Co), or nickel (Ni), such that a direction of the light-emitting element ED1 directed toward the magnet MG may be aligned.

Next, with reference to FIG. 10B, the light-emitting element ED1, which has been moved toward the assembling substrate 2000 by the magnet MG, may be self-assembled to the assembling substrate 2000 by an electric field formed between a plurality of assembling electrodes AE.

With reference to FIG. 10B, the assembling substrate 2000 includes an assembling substrate 210, the organic layer OL, the plurality of assembling electrodes AE, and an assembling insulation layer IL.

Specifically, the plurality of light-emitting elements ED1 may be self-assembled to the opening portion OLH of the organic layer OL by applying voltages to the plurality of assembling electrodes AE. For example, an electric field may be formed by applying different alternating current voltages to a plurality of first assembling electrodes AE1 and a plurality of second assembling electrodes AE2. The light-emitting element ED1 may have a polarity by being dielectrically polarized by the electric field. Further, the dielectrically polarized light-emitting element ED1 may be fixed or moved in a particular direction by dielectrophoresis (DEP), i.e., the electric field. Therefore, the plurality of light-emitting elements ED1 may be temporarily self-assembled inside the opening portion OLH of the assembling substrate 2000 by using the dielectrophoresis.

Meanwhile, the organic layer OL includes a first organic layer OL1 and a second organic layer OL2. A thickness of the organic layer OL, which may be formed by one process, is limited. If the thickness of the organic layer OL is at a predetermined level or lower, the light-emitting element ED1 self-assembled in the opening portion OLH of the organic layer OL, may not be properly seated in the opening portion OLH. On the contrary, in case that the thickness of the organic layer OL is excessively large, it may be difficult to attach the light-emitting element ED1 self-assembled inside the opening portion OLH of the organic layer OL, to the donor 3000. Therefore, the thickness of the organic layer OL may be adjusted by forming the organic layer OL as a plurality of layers.

The organic layer OL includes the plurality of opening portions OLH. Each of the plurality of opening portions OLH formed by opening a part of the organic layer OL, may be an area in which the plurality of light-emitting elements ED1 is self-assembled. Thereafter, the plurality of opening portions OLH may each be formed at positions respectively corresponding to the plurality of subpixels SP of the display device 1100. The plurality of opening portions OLH may be disposed to respectively correspond to the plurality of subpixels SP in a one-to-one manner. The light-emitting elements ED1 self-assembled in the plurality of opening portions OLH may be transferred to the plurality of subpixels SP in an intact manner.

The assembling insulation layer IL may be disposed on the organic layer OL and protect a plurality of assembling lines AL, the plurality of assembling electrodes AE, and the organic layer OL from the fluid WT, thereby suppressing a defect such as corrosion of the plurality of assembling lines AL.

After the self-assembling is completed, the fluid WT may be evaporated from the assembling substrate 2000. In this case, the light-emitting element ED1 may be fixed to the inside of the opening portion OLH by forming an electric field between the assembling electrodes AE until the fluid WT is completely evaporated. Further, the electric field may be removed after the assembling substrate 2000 is completely dried. In this case, even after the electric field is removed, the light-emitting element ED1 may be temporarily fixed to the assembling substrate 2000 by a van der Waals force.

Next, with reference to FIG. 10C, the plurality of light-emitting elements ED1 of the assembling substrate 2000 is transferred to the donor 3000.

First, with reference to FIG. 10C, the assembling substrate 2000 and the donor 3000 are aligned so that the plurality of light-emitting elements ED1 and the donor 3000 face one another. For example, the assembling substrate 2000 and the donor 3000 may be aligned so that a first alignment pattern of the assembling substrate 2000 and a second alignment pattern of the donor 3000 overlap each other.

After the assembling substrate 2000 and the donor 3000 are aligned, the assembling substrate 2000 and the donor 3000 may be joined, such that the upper portion of the light-emitting element ED1 may be in contact with the donor 3000. In this case, the donor 3000 is made of a material having an adhesive force, such that the upper portions of the plurality of light-emitting elements ED1 may be bonded to the donor 3000 and moved to the donor 3000 from the assembling substrate 2000.

Next, with reference to FIG. 10D, the plurality of light-emitting elements ED1 on the donor 3000 is transferred onto the bonding layer AD of the display panel PN.

First, the donor 3000 and the display panel PN formed with the bonding layer AD are aligned. The display panel PN and the donor 3000 may be aligned after the donor 3000 is disposed so that the plurality of light-emitting elements ED1 of the donor 3000 and the bonding layer AD of the display panel PN face one another. An alignment key AK temporarily attached to the donor 3000, is aligned with a third alignment pattern AP3 of the display panel PN when the display panel PN and the donor 3000 are aligned, such that the donor 3000 and the display panel PN may be aligned. The third alignment pattern AP3 may be a pattern disposed in the non-display area NA of the display panel PN. The third alignment pattern AP3 may be made of the same material as any one of the plurality of electrodes or the plurality of lines disposed on the display panel PN. For example, the third alignment pattern AP3 may have a quadrangular shape in which an X-shaped pattern is disposed. Therefore, the donor 3000 and the display panel PN may be aligned so that the alignment key AK is disposed at a center of an X-shaped portion of the third alignment pattern AP3.

Further, with reference to FIGS. 10D and 10E together, the donor 3000 and the display device 1100 may be joined, such that the light-emitting element ED1 on the donor 3000 may be transferred onto the bonding layer AD. The plurality of light-emitting elements ED1 disposed on the donor 3000 is disposed in the arrangement corresponding to the plurality of subpixels SP, such that all the light-emitting elements ED1 on the donor 3000 may be transferred to the display panel PN at once without selectively transferring the light-emitting element ED1. The plurality of light-emitting elements ED1 transferred to the display panel PN may be temporarily fixed by being attached to the bonding layer AD.

Further, the alignment key AK, together with the plurality of light-emitting elements ED1, may be transferred. The alignment key AK may be transferred onto the third alignment pattern AP3 in the non-display area NA. However, because the alignment key AK transferred to the display panel PN is not connected to a separate connection electrode CE, the light is not emitted.

Next, with reference to FIG. 10F, the light-emitting element ED1 is transferred onto the bonding layer AD of the display device 1100, and then the first connection electrode CE1 and the second connection electrode CE2 are formed, such that the light-emitting element ED1 may be electrically connected to the driving transistor DT and the power line VDD.

First, the second planarization layer 1118 and the third planarization layer 1119, which cover the plurality of light-emitting elements ED1, are formed. Further, the contact holes, through which the first electrode 124 and the second electrode 125 of each of the plurality of light-emitting elements ED1 are exposed, may be formed in the third planarization layer 1119. The contact holes, through which the first reflective electrode RE1 and the second reflective electrode RE2 are exposed, may be formed in the third planarization layer 1119, the second planarization layer 1118, and the bonding layer AD.

Next, the first connection electrode CE1 and the second connection electrode CE2 may be formed on the third planarization layer 1119. Further, an electrically conductive material layer may be formed on the front surface of the substrate 110, and the first connection electrode CE1 and the second connection electrode CE2 may be formed by patterning the electrically conductive material layer.

Therefore, in the display device 1100 and the method of manufacturing the display device 1100 according to one or more embodiments of the present disclosure, the plurality of light-emitting elements ED1 may be self-assembled, in the arrangement corresponding to the plurality of subpixels SP, onto the assembling substrate 2000, and then the plurality of light-emitting elements ED1 on the assembling substrate 2000 may be transferred to the display panel PN by using the donor 3000. In case that the light-emitting element ED1 is self-assembled by using the electric field, it is possible to exclude the process of aligning the plurality of light-emitting elements ED1 to correspond to the intervals between the plurality of subpixels SP and then transferring the plurality of light-emitting elements ED1 from the wafer to the donor 3000. In addition, the light-emitting element ED1 may be easily self-assembled at the exact position by using the electric field and the plurality of opening portions OLH, which may minimize or at least reduce an alignment error. Therefore, the plurality of light-emitting elements ED1 may be self-assembled in the arrangement corresponding to the subpixel SP by using the assembling substrate 2000, and the plurality of light-emitting elements ED1 may be transferred to the display panel PN in an intact manner, which may minimize or at least an alignment error of the plurality of light-emitting elements ED1 and simplify the transfer process.

The embodiments of the present disclosure can also be described as follows:

According to one or more embodiments of the present disclosure, there is provided a light-emitting element. The light-emitting element comprises a first semiconductor layer; a light-emitting layer on the first semiconductor layer; a second semiconductor layer on the light-emitting layer; a second electrode on the second semiconductor layer; and a first electrode on the first semiconductor layer and spaced apart from the light-emitting layer and the second semiconductor layer, wherein the first semiconductor layer comprises one or more concave patterns between the first electrode and the second electrode.

A width of the first semiconductor layer above the concave pattern may increase in a downward direction.

A minimum width of the first semiconductor layer in the concave pattern may be smaller than a width of a top surface of the first semiconductor layer and a width of a bottom surface of the first semiconductor layer.

At least a part of the first electrode may be disposed outward of the light-emitting layer, the second semiconductor layer, and the second electrode.

The first electrode may be disposed on a flat top surface of the first semiconductor layer extending from the concave pattern.

The first semiconductor layer may further comprise a plurality of light extraction patterns along the concave pattern.

The plurality of light extraction patterns may have an inclination of 73 degrees.

The light-emitting element may further comprise an encapsulation layer configured to cover a top surface of the light-emitting element and a side surface of the light-emitting element, wherein the encapsulation layer may be disposed only above the concave pattern.

A plurality of light extraction patterns may be disposed on a surface of the concave pattern.

According to one or more embodiments of the present disclosure, there is provided a display device. The display device comprises a substrate comprising a plurality of subpixels; a plurality of light-emitting elements disposed in the plurality of subpixels on the substrate; a plurality of transistors disposed on the substrate; and a connection electrode configured to connect the plurality of transistors and the plurality of light-emitting elements, wherein the plurality of light-emitting elements each comprises at least one concave pattern disposed on a side surface thereof, and wherein the connection electrode is disposed to overlap a part of the concave pattern.

The plurality of light-emitting elements each may comprise a first semiconductor layer; a light-emitting layer on the first semiconductor layer; a second semiconductor layer on the light-emitting layer; a second electrode on the second semiconductor layer; and a first electrode on the first semiconductor layer and spaced apart from the light-emitting layer and the second semiconductor layer, and wherein the concave pattern may be disposed on the first semiconductor layer.

The first semiconductor layer may comprise a first portion below the concave pattern; a second portion above the first portion and comprising the concave pattern; and a third portion on the second portion, and wherein the first electrode may be disposed on a top surface of the first portion exposed by the second portion.

The display device may further comprise a planarization layer configured to surround side surfaces of the plurality of light-emitting elements, wherein the planarization layer may fill the concave pattern.

The display device may further comprise a plurality of assembling electrodes on the substrate and configured to overlap the plurality of light-emitting elements.

The plurality of assembling electrodes and the plurality of light-emitting elements may be electrically connected.

The display device may further comprise a plurality of reflective electrodes on the substrate and to overlap the plurality of light-emitting elements; and a bonding layer on the substrate and bonded to the plurality of light-emitting elements.

The plurality of light-emitting elements may comprise a first light-emitting element, a second light-emitting element, and a third light-emitting element that may have different planar shapes.

The plurality of light-emitting elements may have the concave patterns having shapes that vary depending on a wavelength of light to be emitted.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A light-emitting element, comprising:
a first semiconductor layer;
a light-emitting layer on the first semiconductor layer;
a second semiconductor layer on the light-emitting layer;
a second electrode on the second semiconductor layer; and
a first electrode on the first semiconductor layer, the first electrode spaced apart from the light-emitting layer and the second semiconductor layer,
wherein the first semiconductor layer comprises one or more concave patterns between the first electrode and the second electrode.

2. The light-emitting element of claim 1, wherein a width of the first semiconductor layer above a concave pattern of the one or more concave patterns increases in a downward direction.

3. The light-emitting element of claim 1, wherein a minimum width of the first semiconductor layer in a concave pattern of the one or more concave patterns is smaller than a width of a top surface of the first semiconductor layer and a width of a bottom surface of the first semiconductor layer.

4. The light-emitting element of claim 3, wherein at least a part of the first electrode is outward of the light-emitting layer, the second semiconductor layer, and the second electrode.

5. The light-emitting element of claim 4, wherein the first electrode is on a flat top surface of the first semiconductor layer that extends from the concave pattern.

6. The light-emitting element of claim 1, wherein the first semiconductor layer further comprises a plurality of light extraction patterns along a concave pattern of the one or more concave patterns.

7. The light-emitting element of claim 6, wherein the plurality of light extraction patterns have an inclination of 73 degrees.

8. The light-emitting element of claim 1, further comprising:
an encapsulation layer covering a top surface of the light-emitting element and a side surface of the light-emitting element,
wherein the encapsulation layer is above a concave pattern of the one or more concave patterns.

9. The light-emitting element of claim 1, wherein the concave pattern is formed in a crystal direction of the first semiconductor layer.

10. A display device, comprising:
a substrate comprising a plurality of subpixels;
a plurality of light-emitting elements in the plurality of subpixels on the substrate;
a plurality of transistors on the substrate; and
a connection electrode connecting the plurality of transistors and the plurality of light-emitting elements,
wherein each of the plurality of light-emitting elements comprises one or more concave patterns on a side surface of each of the plurality of light-emitting elements, and
wherein the connection electrode overlaps a part of a concave pattern of the one or more concave patterns.

11. The display device of claim 10, wherein a plurality of light extraction patterns are on a surface of the concave pattern.

12. The display device of claim 10, wherein each of the plurality of light-emitting elements comprises:
a first semiconductor layer;
a light-emitting layer on the first semiconductor layer;
a second semiconductor layer on the light-emitting layer;
a second electrode on the second semiconductor layer; and
a first electrode on the first semiconductor layer, the first electrode spaced apart from the light-emitting layer and the second semiconductor layer, and
wherein the concave pattern is on the first semiconductor layer.

13. The display device of claim 12, wherein the first semiconductor layer comprises:
a first portion below the concave pattern;
a second portion above the first portion, the second portion comprising the concave pattern; and
a third portion on the second portion, and
wherein the first electrode is on a top surface of the first portion, the top surface exposed by the second portion.

14. The display device of claim 10, further comprising:
a planarization layer surrounding side surfaces of the plurality of light-emitting elements,
wherein the planarization layer fills the concave pattern.

15. The display device of claim 10, further comprising:
a plurality of assembling electrodes on the substrate, the plurality of assembling electrodes overlapping the plurality of light-emitting elements.

16. The display device of claim 15, wherein the plurality of assembling electrodes and the plurality of light-emitting elements are electrically connected.

17. The display device of claim 10, further comprising:
a plurality of reflective electrodes on the substrate, the plurality of reflective electrodes overlapping the plurality of light-emitting elements; and
a bonding layer on the substrate, the bonding layer bonded to the plurality of light-emitting elements.

18. The display device of claim 17, wherein the plurality of light-emitting elements comprise a first light-emitting element, a second light-emitting element, and a third light-emitting element, the first light-emitting element, the second light-emitting element, and the third light-emitting element having different planar shapes.

19. The display device of claim 17, wherein the plurality of light-emitting elements have the one or more concave patterns having shapes that vary depending on a wavelength of emitted light.

20. A method of manufacturing a light-emitting element, comprising:
disposing a first semiconductor layer, a light-emitting layer, a second semiconductor layer, and a second electrode on a wafer;
mesa etching a partial area of the light-emitting layer and the second semiconductor layer to form a mesa area;
forming a first cover layer that covers the mesa area;
etching the first semiconductor layer in an area that is not covered by the first cover layer to form a concave pattern;
forming a second cover layer;
etching the first semiconductor layer in an area that is covered by the second cover layer and removing the second cover layer to form a first electrode on the first semiconductor layer;
forming a third cover layer that covers only the concave pattern, a lower area of the concave pattern and the first electrode;
forming a encapsulation layer on the third cover layer; and
removing the third cover layer.
